(19) United States
(12) Patent Application Publication
(10) Pub. No.: US 2025/0029930 A1
(43) Pub. Date: Jan. 23, 2025

(54) INTERPOSERS, SEMICONDUCTOR PACKAGES AND METHODS OF PRODUCING THE SAME

(71) Applicant: TOPPAN HOLDINGS INC., Tokyo (JP)

(72) Inventors: Fusao TAKAGI, Tokyo (JP); Masahiro KOSUGI, Tokyo (JP); Takashi FUJITA, Tokyo (JP); Shuji KIUCHI, Tokyo (JP)

(73) Assignee: TOPPAN HOLDINGS INC., Tokyo (JP)

(21) Appl. No.: 18/805,153

(22) Filed: Aug. 14, 2024

Related U.S. Application Data
(63) Continuation of application No. PCT/JP2023/002842, filed on Jan. 30, 2023.

(30) Foreign Application Priority Data
Feb. 15, 2022 (JP) 2022-021044
Nov. 28, 2022 (JP) 2022-188815

(51) Int. Cl. H01L 23/538; H01L 21/48; H01L 21/66; H01L 23/00; H01L 23/498; H01L 25/10

(52) U.S. Cl. CPC H01L 23/5383; H01L 21/4857; H01L 22/14; H01L 22/20; H01L 23/49894; H01L 25/105; H01L 24/16; H01L 24/32; H01L 24/73; H01L 2224/16157; H01L 2224/32225; H01L 2224/73204; H01L 2225/1041

(57) ABSTRACT

An interposer including an inner layer structure including at least one inner wiring layer; a first outer layer structure disposed on a first surface of the inner layer structure, the first outer layer structure having rigidity higher than the inner layer structure; and a second outer layer structure disposed on a second surface of the inner layer structure, the second outer layer structure having rigidity higher than the inner layer structure, the inner wiring layer includes wiring disposed on a surface of a first insulating resin layer, which is a photosensitive insulating resin, and a conductive member connected to the wiring and penetrating the first insulating resin layer, the first outer layer structure includes a second insulating resin layer and a conductive member penetrating the second insulating resin layer, the second outer layer structure includes a third insulating resin layer and a conductive member penetrating the third insulating resin layer.

### CROSS-REFERENCE TO RELATED PATENT APPLICATIONS

This application is a continuation application filed under 35 U.S.C. § 111 (a) claiming the benefit under 35 U.S.C. §§ 120 and 365 (c) of International Patent Application No. PCT/JP2023/002842, filed on Jan. 30, 2023, which is based upon and claims the benefit to Japanese Patent Application No. 2022-021044, filed on Feb. 15, 2022, and to Japanese Patent Application No. 2022-188815, filed on Nov. 28, 2022, the disclosures of all which are incorporated herein by reference in their entirety.

### TECHNICAL FIELD

The present invention relates to interposers for mounting semiconductor devices thereon, semiconductor packages in which semiconductor devices are mounted on an interposer, and methods of producing the interposers and the semiconductor devices.

### BACKGROUND

In recent years, a system in package (SiP), in which a plurality of different types of semiconductor devices (semiconductor chips) are mounted on an interposer to provide a single semiconductor package with high functionality, has been put to practical use. With this technique, a “semiconductor package” as a single semiconductor device with high functionality can be obtained without increasing the process cost.

Common examples of the semiconductor devices mounted in the SiP include high bandwidth memories (HBMs), which are stacked DRAMs. In general, HBMs have a narrow pitch of connection terminals, such as approximately 55 μm, and interposers are also required to have the same level of connection terminals.

While such an interposer is connected to an FC-BGA substrate, the FC-BGA substrate has the coefficient of thermal expansion (CTE) of approximately 18 ppm/° C., which is higher than the CTE of semiconductor chips of 3 ppm/° C. Therefore, the interposers are required to have a function of reducing the CTE mismatch between the semiconductor chips and the FC-BGA substrate.

Further, for convenience of assembling semiconductor packages, it is desired to mount semiconductor devices on an interposer and then mount the interposer to an FC-BGA substrate. Therefore, the interposer must be provided as an independent unit separate from the FC-BGA substrate.

PTL 1 discloses a method of producing a semiconductor package (1) while suppressing warpage of an interposer, the method including the steps of: preparing a laminate (20) including a plate-like first reinforcement member (5A), a laminate (2A) for a first conductor pattern wiring substrate, and a plate-like second reinforcement member (4A) disposed on a second conductor pattern (221); heating the laminate (20) to thermally cure an insulating layer; selectively removing a part of the first reinforcement member (5A) to form an aperture through which a first conductor pattern (224) is exposed; selectively removing a part of the second reinforcement member (4A) to form an aperture 41 through which the second conductor pattern (221) is exposed; and connecting a semiconductor element (3) to the second conductor pattern (221) exposed from the aperture in the second reinforcement member (4A).

### CITATION LIST

### Patent Literature

PTL 1: WO 2013-065287

### SUMMARY OF INVENTION

### Summary of the Invention

### Technical Problem

Since the interposer described in PTL 1 has a structure in which a fiber substrate is impregnated with a resin composition, the diameter of vias that can be formed is limited to 50 μm. Further, the via-to-via pitch is limited to 130 μm, making it difficult to mount an HBM, which is a stacked DRAM.

Furthermore, in conventional interposers and semiconductor packages using the same, such as fan-out packages and silicon interposers, it is not assumed that the interposer itself is inspected before a process of mounting the semiconductor devices.

Therefore, in conventional production methods, a plurality of chips are mounted on an interposer without inspection and guarantee of the interposer itself.

As a result, the yield of semiconductor packages is the sum of the interposer manufacturing defects and the chip mounting defects, and these cannot be separated from each other.

Specifically, the SiP manufacturing yield can be simply expressed by the following estimation formula (1).
“Interposer yield” (Y_{INTERPOSER}): (value between 0 and 1)
Geometric mean yield of mounting of semiconductor chips (“mounting yield” (Y ASSEMBLY): (value between 0 and 1)
Number of semiconductor devices mounted on a SiP: N (integer greater than of equal to 1)
SiP manufacturing yield (Y_{TOTAL}): (value between 0 and 1)

$$The SiP manufacturing yield is as follows : ( {Y}_{TOTAL} ) = ( {Y}_{INTERPOSER} ) \times {( {Y}_{ASSEMBLY} )}^{N} \qquad ( 1 )$$

As described in formula (1), the SiP manufacturing yield is the product of the interposer yield and the geometric mean yield of mounting of chips raised to the power of the number of chips.

When the “interposer yield” (Y_{INTERPOSER}) and “mounting yield” (Y_{ASSEMBLY}) are both 90%, and 7 chips are mounted in a SiP,

$$( {Y}_{INTERPOSER} ) = ( {Y}_{ASSEMBLY} ) = 90 \% , N = 7 \qquad ( 2 )$$

$$( {Y}_{TOTAL} ) = {0.9}^{7} = 47.8 \% \qquad ( 3 )$$

This causes the problem that the overall SiP manufacturing yield is extremely low even if each process yield is 90%.

In the SiP in which a plurality of semiconductor devices are mounted to form a single semiconductor package, even a single manufacturing defect or mounting defect in the interposer leads to disposal of the entire SiP (all the plurality of semiconductor devices) even if individual semiconductor devices are inspected and fount to be non-defective products. As a result, as the number of mounted chips increases, the SiP manufacturing yield decreases exponentially and the number of discarded non-defective chips increases.

Furthermore, in conventional production methods, the entire mounted semiconductor devices are sealed in a molding resin, and therefore individual semiconductor devices having manufacturing defects cannot be replaced for repair.

The present invention has been made to provide an interposer capable of forming connection terminals for semiconductor devices with a narrow pitch of 60 μm or less, and capable of electrical inspection of the interposer itself before mounting semiconductor devices.

### Solution to Problems

In order to solve the above problem, one of representative interposers of the present invention includes:
an inner layer structure including at least one inner wiring layer;
a first outer layer structure disposed on a first main surface of the inner layer structure, the first outer layer structure having rigidity higher than that of the inner layer structure; and
a second outer layer structure disposed on a second main surface of the inner layer structure, the second outer layer structure having rigidity higher than that of the inner layer structure, wherein
the first outer layer structure covers at least the first surface of the inner layer structure,
the second outer layer structure covers at least the second surface of the inner layer structure,
the inner wiring layer includes wiring disposed on a surface of a first insulating resin layer, which is a photosensitive insulating resin, and a conductive member connected to the wiring and penetrating the first insulating resin layer,
the first outer layer structure includes a second insulating resin layer and a conductive member penetrating the second insulating resin layer,
the second outer layer structure includes a third insulating resin layer and a conductive member penetrating the third insulating resin layer,
the second insulating resin layer is a non-photosensitive resin containing a filler and no fiber substrate,
the third insulating resin layer is a non-photosensitive resin containing a filler and a fiber substrate, and
the first outer layer structure and/or the second outer layer structure includes a terminal connectable to a semiconductor device on a surface opposite to that connected to the inner layer structure, the terminal being capable of being subjected to electrical inspection.

### Advantageous Effects of Invention

The present invention has been made to provide an interposer capable of forming connection terminals for semiconductor devices with a narrow pitch of 60 μm or less, and capable of electrical inspection of the interposer itself before mounting semiconductor devices.

Problems, configurations and effects other than those described above will be apparent from the description of embodiments below.

### BRIEF DESCRIPTION OF THE DRAWINGS

FIGS. 1A and 1B are cross-sectional diagrams of an interposer and a semiconductor package of a first embodiment.

FIG. 2 is a diagram showing the relationship between the overall CTE and outer wiring layer CTE.

FIG. 3 is a diagram showing the relationship between the manufacturing defect rate and thickness.

FIG. 4 is a schematic diagram of a modified example of the interposer of the first embodiment.

FIG. 5 is a schematic diagram of another modified example of the interposer of the first embodiment.

FIG. 6 is a schematic diagram of another modified example of the interposer of the first embodiment.

FIGS. 7A-7E are diagrams illustrating a production process of the interposer and the semiconductor package of the first embodiment.

FIGS. 8A-8E are diagrams illustrating a production process of the interposer and the semiconductor package of the first embodiment.

FIGS. 9A-9D are diagrams illustrating a production process of the interposer and the semiconductor package of the first embodiment.

FIGS. 10A-10C are diagrams illustrating a production process of the interposer and the semiconductor package of the first embodiment.

FIGS. 11A-11E are diagrams illustrating a production process of an interposer of a modified example of the first embodiment.

FIGS. 12A-12C are diagrams illustrating a production process of the semiconductor package of the first embodiment.

FIGS. 13A and 13B are diagrams illustrating a production process of the semiconductor package of the first embodiment.

FIG. 14 is a schematic diagram of an interposer of a second embodiment.

FIGS. 15A-15E are diagrams illustrating a method of producing an interposer of the second embodiment.

FIGS. 16A and 16 B are schematic diagrams of an interposer and a semiconductor package of a third embodiment.

FIGS. 17A-17C are diagrams illustrating a method of producing an interposer of the third embodiment.

FIGS. 18A and 18B are diagrams illustrating a method of producing an interposer of the third embodiment.

FIGS. 19A and 19B are schematic diagrams of an interposer and a semiconductor package of a fourth embodiment.

FIGS. 20A and 20B are diagrams illustrating a method of producing an interposer and a semiconductor package of the fourth embodiment.

FIG. 21 is a diagram illustrating a method of producing a semiconductor package of the fourth embodiment.

FIG. 22 is a diagram illustrating an outline of a four-point bending test.

FIG. 23 is a table showing standard values of deflection rate in a four-point bending test.

FIG. 24 is a diagram showing the relationship between the interposer thickness and the ratio of the load to deflection in a four-point bending test.

FIGS. 25A and 25B are schematic diagrams of an interposer and a semiconductor package of a fifth embodiment.

FIGS. 26A-26E are diagrams illustrating a method of producing an interposer and a semiconductor package of the fifth embodiment.

FIGS. 27A-27D are diagrams illustrating a method of producing an interposer and a semiconductor package of a modified example 1 of the fifth embodiment.

FIGS. 28A-28D are diagrams illustrating a method of producing an interposer and a semiconductor package of a modified example 2 of the fifth embodiment.

### DETAILED DESCRIPTION

With reference to the drawings, some embodiments of the present invention will be described. It should be noted that the present invention is not limited to the following embodiments. In the following description of the drawings, the same components are denoted by the same reference signs. The designations “first” and “second” do not particularly limit the order or configuration but are used for the convenience of description.

In order to facilitate understanding of the invention, the position, size, shape, extent, and the like of each component shown in the drawings may not represent the actual position, size, shape, extent, and the like. Therefore, the present invention is not necessarily limited to the position, size, shape, range, and the like disclosed in the drawings.

The “surface” described herein may refer not only to a surface of a plate-like member, but also to an interface of layers included in the plate-like member and substantially parallel to the surface of the plate-like member. Further, the “upper surface” and “lower surface” refer to surfaces shown on the upper side and lower side of the plate-like member or the layers included in the plate-like member as viewed in the drawings. In addition, the “upper surface” and “lower surface” may also be called “first surface” and “second surface,” respectively.

The “side surface” refers to a portion extending across the thickness of the surface or layer of the plate-like member or the layers included in the plate-like member. Further, a part of the surface and the side surface may also be collectively referred to as an “end portion.”

“Upper” refers to the upper side in the vertical direction when the plate-like member or the layers are disposed horizontally. Further, “upper” and “lower” may also be referred to as the “positive Z-axis direction” and “negative Z axis direction”, respectively, which are opposite directions, and the horizontal direction may also be referred to as “X axis direction” or “Y axis direction.”

The “planar shape” and “plan view” refer to the shape when the surface or layer is viewed from above. Further, the “cross-sectional shape” and “cross-sectional view” refer to the shape as viewed in the horizontal direction when the plate-like member or the layers are cut in a specific direction.

The “center portion” refers to a center portion other than the peripheral portion of the surface or layer. The “center direction” refers to a direction from the peripheral portion of the surface or layer toward the center of the planar shape of the surface or layer.

### First Embodiment

### <Structure of Interposer>

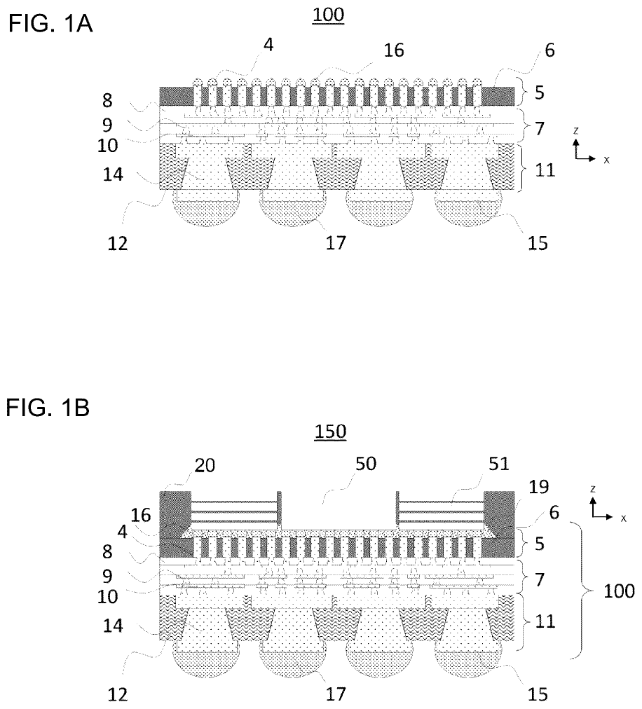

FIG. 1A is an example schematic cross-sectional diagram of an interposer 100 according to a first embodiment of the present invention. FIG. 1B is a schematic cross-sectional diagram of a semiconductor package 150 in which semiconductor devices 50 and 51 are mounted on the interposer 100 of the first embodiment.

In the present disclosure, the interposer 100 has the upper and lower surfaces, and the side on which the semiconductor devices 50 and 51 are mounted is referred to as a “first surface-side” and the side connected to a motherboard or FC-BGA substrate is referred to as a “second surface-side.”

In the present embodiment, second connection terminals 17 are disposed on the second surface-side of a second outer layer structure 11. The second connection terminals 17 serve as connection terminals to an FC-BGA substrate or motherboard.

The interposer 100 in FIG. 1A is mainly composed of a first outer layer structure 5, an inner layer structure 7 and the second outer layer structure 11.

The first outer layer structure 5 is disposed on the upper side of the inner layer structure 7, that is, on the positive side in the Z axis direction. Further, the first outer layer structure 5 is formed of a second insulating resin layer 6, with conductive members 4 penetrating the second insulating resin layer 6 in the Z axis direction. The conductive members 4 penetrating the second insulating resin layer 6 can function as pads of external connection terminals of the first outer layer structure 5.

Furthermore, first connection terminals 16 are disposed on the first surface-side of the first outer layer structure 5.

The inner layer structure 7 is disposed between the first outer layer structure 5 and the second outer layer structure 11.

The inner layer structure 7 includes at least one inner wiring layer, and the inner wiring layer includes a first insulating resin layer 8, wiring 10 disposed on a surface of the first insulating resin layer, and conductive members connected to the wiring 10 and penetrating the first insulating resin layer in the Z axis direction. The conductive members penetrating the first insulating resin layer function as vias 9 of the inner wiring layer.

Further, the first connection terminals (solders) 16 are disposed on the first surface-side of the first outer layer structure 5.

The second outer layer structure 11 is disposed on the lower side of the inner layer structure 7, that is, on the negative side in the Z axis direction.

Further, the second outer layer structure 11 is formed of a third insulating resin layer 12, with conductive members penetrating the third insulating resin layer 12 in the Z axis direction. The conductive members penetrating the third insulating resin layer 12 are connected to the outermost wiring layer of the inner layer structure 7 and can function as pads of external connection terminals of the second outer layer structure 11.

Further, pads 15 of external connection terminals and the second connection terminals (solder) 17 are disposed on the second surface-side of the second outer layer structure 11.

In the thickness of the interposer 100 in the Z axis direction, it is preferred that the total thickness of the inner layer structure 7, the first outer layer structure 5 and the second outer layer structure 11 is 50 μm or greater.

The thicknesses of the first outer layer structure 5 and the second outer layer structure 11 of the interposer 100 in the present embodiment are not limited to the thicknesses adopted in the present embodiment, but when the first outer layer structure 5 and the second outer layer structure 11 have physical rigidity higher than that of the inner layer structure 7, it is preferred that the sum of the thicknesses of the first outer layer structure 5 and the second outer layer structure 11 is greater than the thickness of the inner layer structure 7. That is, it is preferred that the sum of the thicknesses of the first outer layer structure 5 and the second outer layer structure 11 is at least half the total thickness of the interposer 100.

### <Structure of Semiconductor Package>

FIG. 1B shows the semiconductor package 150 in which the semiconductor devices 50 and 51 are fixed to the first surface-side of the interposer 100 described referring to FIG. 1A, using an underfill 19 and a molding resin 20.

The first connection terminals 16 and the second connection terminals 17 are formed of solder, but the types and composition of the solder are not limited by the present invention, and known conductive materials can be used. Further, the first connection terminals 16 in FIGS. 1A and 1B are formed flush on the upper side of the conductive members 4 of the first outer layer structure 5, but the positional relationship and shape of the first connection terminals 16 and the conductive members 4 are not limited to this structure.

Similarly, the second connection terminals 17 are formed to match the pads 15 of the external terminals on the vias 14 of the second outer layer structure 11 but are not necessarily limited to this structure.

### <First Insulating Resin Layer, Second Insulating Resin Layer and Third Insulating Resin Layer>

The interposer 100 in the embodiment shown in FIG. 1A, when applied as an interposer for a SiP in which a plurality of semiconductor devices are mounted, requires fine wiring with a wiring rule of at least L/S=8/8 μm or less. Therefore, the thickness of the first insulating resin layer 8 constituting the inner layer structure 7 is preferably 25 μm or less.

As a result, the inner layer structure 7 must be flexible without physical rigidity even when the inner wiring layer is a multilayer circuit.

Therefore, in this example, a fine wire routing structure required for the SiP interposer in which a plurality of semiconductor devices are mounted is formed by the inner layer structure 7. In addition, the input/output terminal portions of the inner layer structure 7 are formed by the first outer layer structure 5 and the second outer layer structure 11 having physical rigidity. Since the input/output terminal portions have more leeway in wiring rules compared to the fine wiring of the inner layer structure 7, the first outer layer structure 5 and the second outer layer structure 11 can be made of a rigid material.

Therefore, due to the configuration in which the inner layer structure 7 having no physical rigidity is sandwiched between the first outer layer structure 5 and the second outer layer structure 11 having physical rigidity, the interposer 100 can be provided as a rigid device as a whole. That is, the circuit fineness and physical rigidity are functionally divided between the inner layer structure 7 and the two outer layer structures, and the combination of these opposing properties results in an interposer that is excellent in both properties.

### <CTE and Elastic Modulus of Outer Layer Structures>

The second insulating resin layer 6 and the third insulating resin layer 12 constituting the first outer layer structure 5 and the second outer layer structure 11, respectively, are non-photosensitive resin layers containing a filler, and preferably have an elastic modulus of 5 GPa or greater and a coefficient of linear thermal expansion (CTE) of 20 ppm or less. The second insulating resin layer 6 is more preferably selected from built-up resins and molding resins. The third insulating resin layer 12 is more preferably selected from prepregs.

The first insulating resin layer applicable to the inner layer structure 7 of the present embodiment is a photosensitive insulating resin, and is made of a material of high CTE and low elasticity, generally having physical properties with a CTE of 20 to 80 ppm/° C. and an elastic modulus of 1.5 GPa or greater and 10 GPa or less.

Accordingly, if an interposer is made only of the above material, it is difficult for the interposer to have a CTE lower than 18 ppm/° C., which is the CTE of an FC-BGA substrate, and function as a buffer against the low CTE of semiconductor devices.

In this regard, the present embodiment, in which the second insulating resin layer 6 and the third insulating resin layer 12 used for the first outer layer structure 5 and the second outer layer structure 11, respectively, have a CTE of 20 ppm/° C. or less and a high elastic modulus of 5 GPa or greater, can make the CTE of the entire interposer 15 ppm/° C. or greater and 30 ppm/° C. or less, which is the CTE of the FC-BGA substrate.

Using the second insulating resin layer 6 and the third insulating resin layer 12 having the CTE of 20 ppm/° C. or less as the first outer layer structure 5 and the second outer layer structure 11, respectively, can achieve the effect of reducing the CTE of the entire interposer 100 as described below.

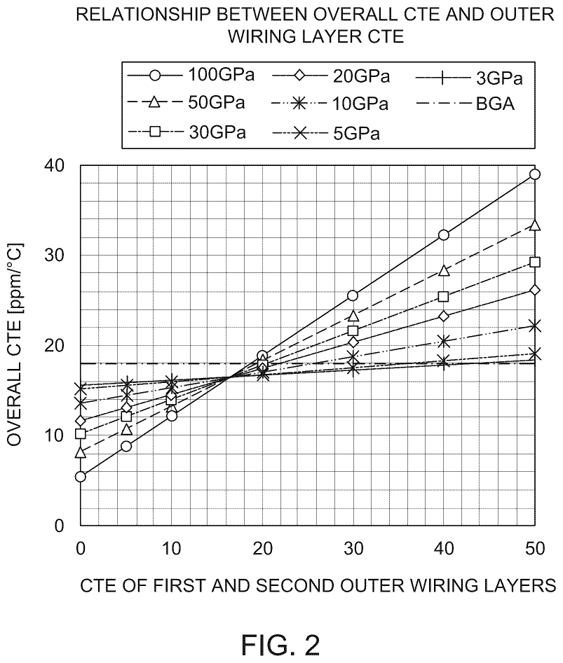

FIG. 2 shows the results of simulating the relationship between the CTE of the entire interposer with a total thickness of 50 μm according to the present invention and the CTE and elastic modulus of the materials used for the first outer layer structure and the second outer layer structure. The Y axis represents the CTE of the entire interposer, and the X axis represents the CTE of the first and second outer wiring layers. The simulation conditions are as follows. The CTE and elastic modulus of the first outer wiring layer and the second outer wiring layer were used as factors in the calculation.

### First Outer Layer Structure

Thickness: 20 μm, copper wiring volume ratio fixed at 10%, CTE and elastic modulus are factors

### Second Outer Layer Structure

Thickness: 20 μm, copper wiring volume ratio fixed at 30%, CTE and elastic modulus are factors

### Inner Layer Structure

Thickness: 10 μm, CTE: 65 ppm/° C., elastic modulus 2 GPa, copper wiring thickness 2 μm, copper wiring volume ratio 85%
Interposer total thickness 50 μm

Reference value: CTE of the entire FC-BGA substrate is 18 ppm/° C., indicated by the dot-dashed line in the graph.

A simulation was performed under these conditions, and the results are shown in the graph of FIG. 2. That is, as seen from FIG. 2, using the first outer layer structure 5 and the second outer layer structure 11 with a CTE of 20 ppm/° C. or less can make the CTE of the entire interposer 100 lower than that of conventional FC-BGA substrates.

Further, the more elastic the material used for the first outer layer structure 5 and the second outer layer structure 11, the greater the effect of reducing the CTE of the entire interposer.

As seen from the above, the CTE of the entire interposer can be effectively reduced when the elastic modulus of the first outer layer structure 5 and the second outer layer structure 11 is 5 GPa or greater, and it is preferred to select a CTE of 20 ppm/° C. or less and an elastic modulus of 5 GPa or greater.

### <Configuration and Residual Copper Ratio of Outer Layer Structure>

In the interposer 100 of the embodiment shown in FIG. 1A, the conductive members 4 of the first outer layer structure 5 and the vias 14 and the pads 15 of the second outer layer structure 11 have functions of electrically connecting the first connection terminals 16 and the second connection terminals 17 to the wiring of the inner layer structure 7. Accordingly, in the first outer layer structure 5 and the second outer layer structure 11, the connection paths generally extend in the Z direction.

On the other hand, in the inner layer structure 7, the wire routing in the Z axis direction and a direction perpendicular to the Z axis, that is, horizontal direction is realized using wiring suitable for miniaturization.

In the present embodiment, the conductive member used for the interposer is basically made of copper, and since the CTE of copper is relatively high at 16 ppm/° C., it is difficult to reduce the CTE of the entire interposer 100 if the copper volume fraction is high in the first outer layer structure 5 and the second outer layer structure 11.

Therefore, the first outer layer structure 5 and the second outer layer structure 11 preferably have a residual copper ratio of 80% or less. More preferably, the residual copper ratio is 50% or less. Still more preferably, the residual copper ratio is 30% or less.

### <Method of Evaluating Rigidity of Interposer>

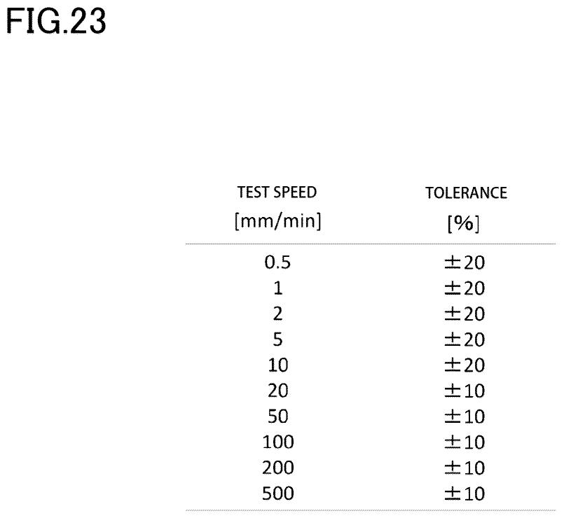

Next, with reference to FIGS. 22 and 23, a method of evaluating the rigidity of the interposer 100 will be described.

FIG. 22 is a diagram illustrating an outline of a four-point bending test.

FIG. 23 is a table showing standard values of test speed in a four-point bending test.

The rigidity of the interposer 100 is assessed by the load and deflection in a bending test of a specimen 101 obtained by processing the interposer 100.

There are a three-point bending test and a four-point bending test in the bending tests, and the present embodiment adopts the four-point bending test.

In the case of a three-point bending test, the bending force applied to a specimen is not uniform, and the inside and outside of the bent portion of the specimen 101 flexes and stretches, respectively. Accordingly, in a laminate composed of multiple layers, such as the interposer 100, the obtained results may vary depending on the arrangement of the materials in the thickness direction.

On the other hand, in the case of a four-point bending test, the bending force applied to the specimen 101 is uniform, resulting in a measurement with high accuracy.

The test conditions for the four-point bending test for evaluating the interposer 100 are as follows.
Dimensions of the specimen 101: 80 mm length×15 mm width×h mm height (thickness of the interposer 100)
Distance between supports L: 66 mm
Indenter radius r1: 2 mm
Distance between indenters L′: 22 mm
Support radius r2: 2 mm
Deflection rate V: calculated by the following formula 1

If the interposer 100 does not have a shape having the specific dimensions for use as a specimen, the interposer 100 is first processed into the specific size (80 mm length×15 mm width×h mm height) as a specimen.

If the interposer 100 has the specific dimensions specified by the test conditions, it may be used as it is as the specimen 101.

A test device that satisfies the test conditions as specified above, such as the distance between supports L, the indenter radius r1, the distance between indenters L′ and the support radius r2, and the test speed described in FIG. 23 is used as a test device in the four-point bending test.

The test device used in the four-point bending test has two cylindrical supports 61 and two cylindrical indenters 60 that satisfy ISO 5893.

The test speed V is calculated by formula (5).

$$\begin{matrix}[ Math . 1 ] & \\ V & ( 5 )\end{matrix}$$

$${ε}_{f}^{′} : strain rate [ 1 / min ]$$

In the present invention, a strain rate of 0.01 [1/min] (1%/min) is selected.

In the four-point bending test, a load of F/2 is applied to each indenter 60 so that a load F is applied to a horizontal surface of the specimen 101 by the indenters.

The load F is a load that causes the deflection rate of the specimen 101 to be the test speed V.

From the load F and deflection obtained in the four-point bending test, a ratio of the load F to the deflection is calculated.

From the ratio thus obtained of the load F of the indenter to the deflection, the rigidity of the interposer can be assessed.

### <Effect of Outer Layer Structure: Suppression of Cracking>

In general, there is a concern that cracking may occur in the inner layer structure 7 due to temperature changes or the like, which causes defects leading to disconnection in the wiring layer. In this regard, the interposer 100 of the present embodiment, in which the first outer layer structure 5 and the second outer layer structure 11 are formed on the entire surfaces of both sides of the inner layer structure 7, respectively, can improve the reliability of the inner layer structure 7 having a fine wiring structure.

In addition, it has been found that, if the first outer layer structure 5 and the second outer layer structure 11 are formed only on a part of the upper and lower surfaces of the inner layer structure 7, respectively, cracking occurs in the inner layer structure 7 due to deformation or stress concentration.

Therefore, the first outer layer structure 5 and the second outer layer structure 11 need to be formed on the entire surfaces of both sides of the inner layer structure 7.

In this example, the physical properties and specific materials used for the first outer layer structure 5 and the second outer layer structure 11 are not particularly specified, but the CTEs of the first outer layer structure 5 and the second outer layer structure 11 are preferably close to each other.

### <Effect of Outer Layer Structure: Inspection>

In the electrical inspection device, the probe load is 0.05 N and a maximum deflection of probe is 0.4 mm. Based on this ratio, a threshold of the indenter load/deflection ratio in the electrical inspection is set to 0.125 N/mm, and a specimen having a value greater than or equal to this ratio can be determined as having sufficient rigidity. In the present embodiment, electrical inspection of the interposer 100 can be satisfactory performed by setting the indenter load/deflection ratio in the four-point bending test of the interposer 100 to 0.125 N/mm or greater. That is, a needle-shaped electrode called a probe used for the electrical inspection can be brought into contact with the electrode exposed on the outermost layer of the interposer 100 to achieve sufficient electrical contact between the probe and the electrode.

For example, for the specimen 101 having the thickness h of 300 μm, the test speed V is 30 mm/sec. When the load F indicates 5.7 N, the deflection is 7 mm, and the indenter load/deflection ratio is 0.814 N/mm, which satisfies the above requirement.

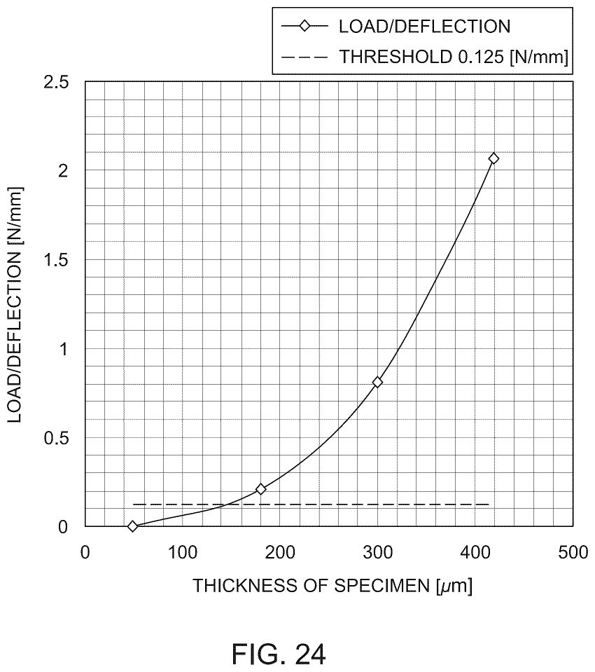

FIG. 24 is an example diagram showing the indenter load/deflection ratio in a four-point bending test of an interposer on the Y axis and the interposer thickness on the X axis, with the solid line indicating their relationship.

In FIG. 24, the dotted line indicates the threshold of 0.125 N/mm for the load/deflection ratio of the probe in the electrical inspection.

By setting the indenter load/deflection ratio in a four-point bending test of the interposer 100 to 0.125 N/mm or greater, the deflection of the probe can exceed the deformation of the interposer due to deflection of the probe. Therefore, by satisfying this condition, sufficient electrical contact between the probe and the electrode can be obtained, enabling electrical inspection with higher reliability.

### <Configuration of Inner Layer Structure>

The inner layer structure 7 shown in FIGS. 1A and 1B is composed of the first insulating resin layer 8, the wiring 10, and the vias 9 of the inner wiring layer penetrating the first insulating resin layer 8. In the present embodiment, the thickness of components of the inner wiring layer, the number of layers, the wiring layer pattern, the shape of vias, the taper direction of vias and the number of vias are not limited by the present embodiment.

The inner layer structure 7 may be formed of a single inner wiring layer or multiple inner wiring layers, and the number of layers and the thickness are not limited by the present embodiment. However, when the interposer 100 of the present embodiment is assumed to be applied to a SiP, it is preferred that multiple inner wiring layers are formed.

### <Wiring Rule of Inner Wiring Layer>

The wiring design rule of the wiring 10 in the inner wiring layer of the inner layer structure 7 shown in FIG. 1A is preferably one that is applicable to fine connections between chips. The L/S is preferably 15/15 μm or less, and more preferably 10/10 μm or less. Still more preferably, the L/S is 8/8 μm or less. The L/S of 15 μm or greater is similar to a conventional FC-BGA wiring rule, which is not suitable for mounting HBMs or the like.

### <Insulating Resin Layer of Outer Layer Structure: Non-Photosensitive Resin>

The second insulating resin layers 6 and the third insulating resin layer 12 which are components of the first outer layer structure 5 and the second outer layer structure 11 in FIG. 1A, respectively, can be selected from non-photosensitive insulating resins, such as epoxy-phenol resins, epoxy-phenol ester resins, epoxy-cyanate resins, cyanate resins, benzocyclobutene, polyimide, polybenzoxazole, and the like. The second insulating resin layer 6 and the third insulating resin layer 12 further contain a filler. The third insulating resin layer 12 contains glass cloth.

### <Insulating Resin Layer of Inner Layer Structure: Photosensitive Resin>

The first insulating resin layer 8 which is a component of the inner layer structure 7 in FIG. 1A can be made of photosensitive insulating resins, and known techniques such as benzocyclobutene, polyimide, polybenzoxazole, epoxy resins, epoxy acrylates, acrylates and the like can be applied.

For example, since it is necessary to form fine wiring with at least L/S=8/8 μm or less in the first insulating resin layer 8, photosensitive insulating resins that are advantageous for formation of fine wiring may be used.

### <First Insulating Resin Layer of Inner Layer Structure: Merits of Photosensitive Resins>

When the first insulating resin layer 8 is a photosensitive insulating resin, microvias having a diameter of 20 μm or less can be formed with a photolithographic positional accuracy of ±3 μm or less. This can maximize the number of semiconductor devices mounted on the interposer and also maximize the number of connection vias.

Photosensitive insulating resins are advantageous in that the time for forming vias does not depend on the number of vias, and vias can be collectively formed. When non-photosensitive insulating resins are used, vias are formed by laser processing or the like, and the processing time increases when the positional accuracy is about ±10 μm and the number of vias increases.

### <Thickness of Insulating Resin Layer of Inner Wiring Layer>

The first insulating resin layer 8 preferably has a thickness of 25 μm or less. The thickness of the first insulating resin layer 8 as described herein refers to the thickness of the resin between the copper wiring patterns on the upper and lower layers. The thickness of the first insulating resin layer of 25 μm or greater makes it difficult to form small vias with a diameter of 20 μm or less and to increase the wiring density. More preferably, the thickness of the first insulating resin layer is 15 μm or less. Still more preferably, it is 10 μm or less.

The thickness of the first insulating resin layer 8 can be appropriately adjusted depending on the applied wiring rule and impedance matching of the circuit.

### <Via Diameter of Inner Wiring Layer>

The vias 9 of the inner wiring layer preferably have a diameter of 40 μm or less. The diameter of the via 9 as described herein refers to the maximum diameter portion. The diameter of the via 9 of 40 μm or greater makes it difficult to achieve high wiring density. More preferably, the diameter is 30 μm or less. Still more preferably, the diameter is 20 μm or less since it contributes to higher wiring density.

### <Thickness of Wiring Layer of Inner Wiring Layer>

The wiring 10 preferably has a thickness of 15 μm or less. More preferably, the thickness of the wiring 10 is 10 μm or less. Still more preferably, it is 8 μm or less. The thickness of 15 μm or greater makes it difficult to form fine wiring with L/S=15/15 μm or less, although it depends on the photoresist used. It is desired that the thickness of the wiring layer is appropriately adjusted depending on the applied wiring rule and impedance matching of the circuit.

### <Wiring Layer Materials of Inner Wiring Layer>

Examples of materials used for the wiring 10 include single metals such as copper, aluminum, nickel, silver, gold, tungsten, iron, niobium, tantalum, titanium and chromium, and alloys thereof, or may include additive elements. Further, a layered structure of these materials may be used. Alternatively, a conductive paste containing these materials, carbon, a conductive resin, or the like may be used.

For example, when forming a metal layer on the first insulating resin layer 8 by sputtering, it is common to form a single layer or an alloy layer of titanium, chromium, nickel, or the like, and then form copper. It is also preferred to form a layer by electroless copper plating or electroless nickel plating on the upper surface of the first insulating resin layer 8. Forming the wiring 10 by electrolytic copper plating is common, simple, inexpensive and desirable.

### <Thickness of Interposer>

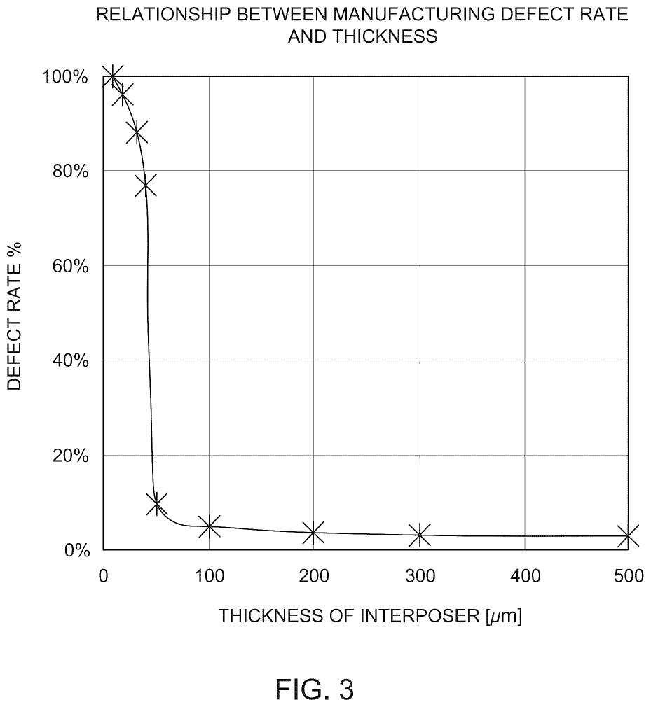

The interposer 100 of the present embodiment preferably has a thickness of at least 50 μm or greater. As shown in FIG. 3, if the thickness is less than 50 μm, the interposer 100 itself cannot be sufficiently rigid, and defects are extremely likely to occur in the subsequent steps of forming external connection terminals, electrical inspection and semiconductor device assembly.

According to the present invention, an electrical inspection can be performed on the interposer alone at the stage before semiconductor devices are mounted on the interposer. Therefore, the yield after production and inspection of the interposer described in formula (4) is as follows:

$$( {Y}_{INTERPOSER} ) = 100 \% \qquad ( 4 )$$

This contributes to improvement in SiP manufacturing yield (Y_{TOTAL}).

### Modification of First Embodiment

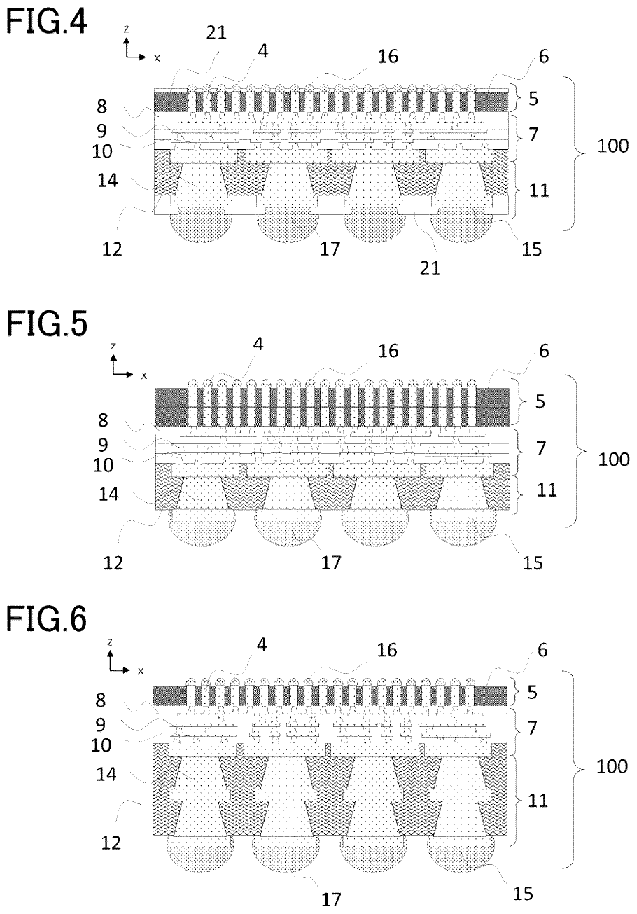

Next, with reference to FIGS. 4 to 6, modified examples of the interposer of the first embodiment will be described.

FIG. 4 is a modified example in which the first connection terminals 16 and the second connection terminals 17 are partitioned by a solder resist 21. The connection terminals may be partitioned by a solder resist.

FIG. 5 is a modified example in which the first outer layer structure 5 is formed of multiple layers. The first outer layer structure 5 may be formed of a single layer or multiple layers. Whether forming a single layer or multiple layers can be appropriately adjusted depending on the rigidity required for the interposer. When the first outer layer structure 5 is formed of multiple layers, the interposer thickness is greater than 50 μm, which is preferred since the rigidity is further increased.

FIG. 6 is a modified example in which the second outer layer structure 11 is formed of multiple layers. The second outer layer structure 11 may be formed of a single layer or multiple layers. Whether forming a single layer or multiple layers can be appropriately adjusted depending on the rigidity required for the interposer.

Further, modified examples of FIGS. 4 to 6 can be combined on the front and rear sides. Further, the conductive members 4 of the second insulating resin layer 6 may include wiring or pads. Furthermore, in addition to the pads 15 of the third insulating resin layer 12 in the second outer layer structure 11, wiring may also be included, and such modified examples are also included in the scope of the present invention. The solder connection interfaces of the first connection terminals 16 and the second connection terminals 17 can be appropriately subjected to surface treatment. The type and thickness of surface treatment are not particularly limited.

### (Brief Description of Production Process)

The method of producing an interposer according to the present invention briefly includes the following steps.

First, a support substrate is prepared, and then an interposer can be obtained by the following steps:
1) a first step of forming a first outer layer structure on the support substrate,
2) a second step of forming an inner layer structure on the upper side of the first outer layer structure,
3) a third step of forming a second outer layer structure on the upper side of the inner layer structure,
4) a fourth step of releasing the first outer layer structure from the support substrate, and
5) a fifth step of forming connection terminals on the outermost layers of the first outer layer structure and the second outer layer structure.

Once the first outer layer structure and the second outer layer structure are completed, the interposer alone can be sufficiently rigid without the support substrate. Therefore, in the subsequent steps, an interposer or a semiconductor package can be produced while being separated from the support substrate.
Since there is no support substrate, it is possible to apply surface treatment, form solder bumps and form protruding electrodes on the connection terminals exposed on both surfaces of the substrate. Thus, the first and second connection terminals can be formed on both surfaces of the interposer.

### (Detailed Description of Production Method)

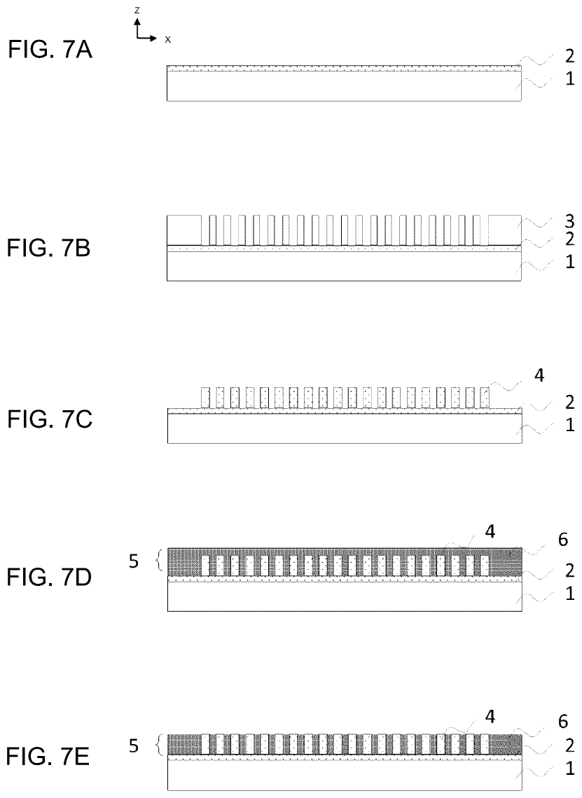

With reference to FIGS. 7A-7E to 10A-10C, the method of producing an interposer and a semiconductor package will be described in detail.

### <Step of Preparing Support Substrate>

First, as shown in FIG. 7A, a support substrate 1 is prepared. The support substrate 1 may be provided by, for example, disposing a laser release layer on a glass substrate, and disposing a metal layer 2 on the laser release layer. The metal layer 2 may be formed by electroless plating or sputtering. Alternatively, a support substrate may be used, in which a carrier copper foil as the metal layer 2 is formed on a copper clad laminate (CCL) substrate with a prepreg therebetween. Here, the carrier copper foil is a copper foil having a three-layer structure of carrier copper foil/release layer/ultrathin copper foil, which can be easily physically released at the interface of the release layer. The type of the support substrate is not limited to those described above, and various known substrates can be used.

FIG. 7B shows a substrate in which a resist pattern 3 is formed by patterning a resist layer formed on the metal layer 2. The thickness of the resist is appropriately determined according to the height of the pads to be formed. In the example of the present invention, a liquid resist is applied at 70 μm, and patterned to form cylindrical pads with a diameter of 25 μm at a pitch of 55 μm as pads of the first connection terminals.

FIG. 7C shows that conductive members 4 are formed by electrolytic copper plating after the step of FIG. 7B. The resist has been removed. The cylindrical conductive members 4 function as the pads. In the present embodiment, the conductive members 4 formed by copper plating have an average height in the Z direction of 65 μm.

Further, before forming a first insulating resin layer 8 constituting a first outer layer structure 5 in the next step, for example, a known copper roughening treatment (CZ treatment) or a silane coupling treatment after displacement tin plating may be appropriately performed in order to enhance adhesion between the copper pattern and the non-photosensitive insulating resin.

FIG. 7D is a diagram showing that a non-photosensitive insulating resin constituting the first outer layer structure 5 is formed. A second insulating resin layer 6 made of a non-photosensitive resin in the present embodiment is a non-photosensitive resin containing at least a filler, and preferably selected from built-up resins and molding resins having an elastic modulus of 5 GPa or greater and a CTE of 20 ppm or less. In the present embodiment, the second insulating resin layer 6 is formed by vacuum lamination using a 70 μm-thick film of molding resin. The type, thickness and production method of the non-photosensitive resin are not limited by the present embodiment, and appropriate materials and production methods can be selected.

FIG. 7E shows that the second insulating resin layer 6 has been ground with a grinder to expose the conductive members 4 as the pads of the first outer layer structure 5. The method of exposing the pads is not limited to the methods of the present embodiment, and known methods such as grinder polishing, buff polishing, belt polishing, flycutting and CMP may be used. Thus, in the present embodiment, the conductive members 4 are formed as the pads in the second insulating resin layer 6 of the first outer layer structure 5. In the present embodiment, the thickness of the first outer layer structure 5 is 60 μm.

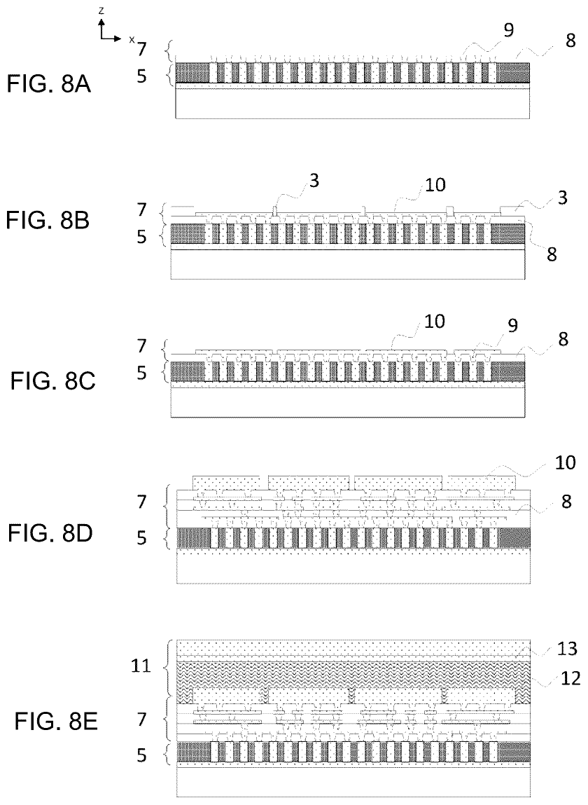

FIG. 8A shows that a first insulating resin layer 8 of an inner layer structure 7 is formed on the upper side of the first outer layer structure 5, and vias 9 are formed. In the present embodiment, a 6 μm-thick first insulating resin layer 8 is formed using a photosensitive insulating resin, and 15 μm diameter vias 9 are formed.

FIG. 8B shows that, after a seed metal layer (not shown) is formed on the first insulating resin layer 8, a resist pattern 3 is formed, and then the vias 9 and wiring 10 of the inner wiring layer are formed by electrolytic plating. In the present embodiment, as a seed metal layer, Ti/Cu=50/300 nm is formed by sputtering, and the resist is formed at a thickness of 5 μm. Thus, after the resist pattern 3 with L/S=2/2 μm is formed, the wiring 10 with a thickness of 2.3 μm (6 μm+2.3 μm, including via) is formed by electrolytic plating.

FIG. 8C is a diagram showing that the resist pattern 3 has been removed and the seed metal layer has then been removed, and the first insulating resin layer 8 and the inner wiring layer formed of the vias 9 and the wiring 10 are formed.

The method of forming the wiring and the method of forming the insulating resin layer are not limited to the methods of the present embodiment, and appropriate forming methods can be selected.

FIG. 8D shows the inner layer structure 7 in which four layers of each of the wiring 10 and the first insulating resin layer 8 are stacked by repeating the steps shown in FIGS. 8A to 8C three times. The thickness of each first insulating resin layer 8 is 6 μm, the thickness of each wiring 10 is 2 μm, and the thickness of the outermost wiring 10 is 12 μm. This is to prevent penetration of the wiring when via holes are formed in a third insulating resin layer 12 of the outer wiring layer with a laser.

As a result, the thickness of the inner layer structure 7 is 36 μm. The thickness of the wiring formed on the outermost layer on the second surface of the inner layer structure may be at least 1.5 times, preferably at least 3 times, and more preferably at least 4 times the thickness of the wiring formed inside the inner wiring layer.

FIG. 8E is a diagram showing a step of forming a second outer layer structure 11. First, a prepreg and a copper foil with a carrier are formed on the upper side of the inner layer structure 7 with a lamination press to constitute the third insulating resin layer 12 of the second outer layer structure 11. The copper foil with a carrier used in this example has a carrier foil thickness of 18 μm and a thin foil-side thickness of 3 μm, and a 3 μm-thick thin copper foil 13 is disposed on the prepreg-side. The thickness of the prepreg is 70 μm.

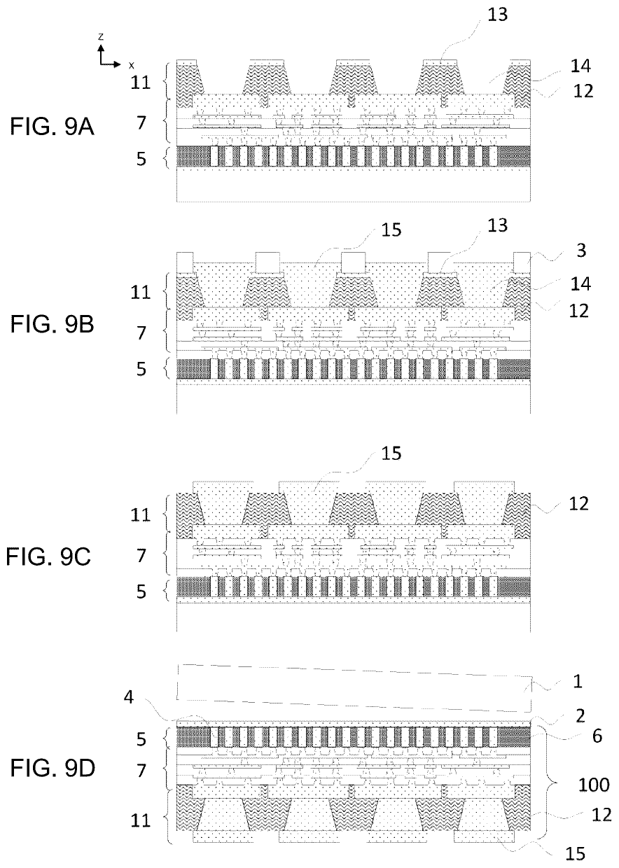

FIG. 9A shows that the carrier foil has been removed from the copper foil with a carrier, and vias 14 are formed in the second outer layer structure 11 using a CO2 laser. Thereafter, the laser apertures are subjected to a desmear treatment, and then electroless copper plating is performed to form 0.6 μm-thick electroless copper plating in the vias (not shown). In the present embodiment, 60 μm diameter vias are formed at a pitch of 150 μm.

FIG. 9B shows that pads 15 are formed by electrolytic copper plating after a resist pattern 3 is formed. In this example, a surface layer of the pads 15 is formed of an 18 μm-thick electrolytic copper plating layer. That is, the thickness of the surface layer of the pad 15 (excluding via) is 18 μm, and the thickness including the via is (via depth 70 μm+18 μm).

FIG. 9C is a diagram showing that the resist pattern 3 has been removed, and the thin copper foil 13 and the electroless copper plating layer have then been removed by etching, and the second outer layer structure 11 is formed. In the present embodiment, the pads 15 having a diameter of 75 μm and a pad thickness of 15 μm are formed at a pitch of 150 μm on the second outer layer structure.

FIG. 9D is a diagram of FIG. 9C inverted upside down, showing a step of removing the support substrate 1. After a protective sheet (not shown) is disposed on a surface of the second outer layer structure 11, the metal layer 2 is removed by etching, and then the protective sheet (not shown) of the second outer layer structure 11 is removed, whereby the interposer 100 in which the conductive members 4 and the pads 15 are exposed on the first outer layer structure 5 and the second outer layer structure 11, respectively, can be obtained. According to the present embodiment, in the steps from FIG. 9D onwards, the first outer layer structure 5 and the second outer layer structure 11 made of materials with high elasticity and low CTE are formed on both surfaces of the inner layer structure 7, respectively, resulting in formation of the interposer 100 with a total thickness of 50 μm or greater. The interposer thus formed is sufficiently rigid to allow transport of the interposer alone. Further, since the support has been removed from the interposer, both surfaces of the interposer are exposed, and the first connection terminals 16 and the second connection terminals 17 can be formed on both surfaces of the interposer, respectively.

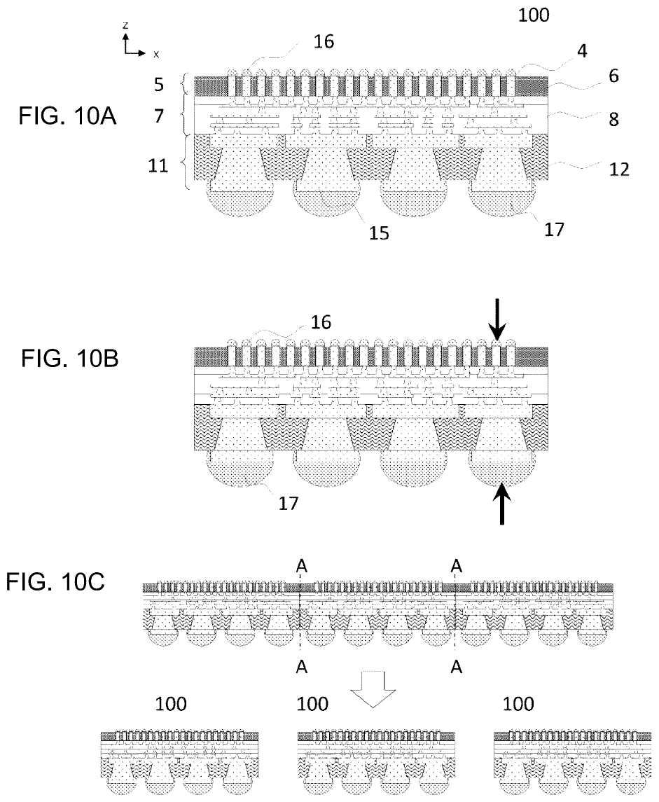

FIG. 10A shows a step of performing a surface treatment on the conductive members 4 (pads) which are external connection terminals of the first outer layer structure 5 and the pads 15 of the external connection terminals of the second outer layer structure 11. The type and thickness of the surface treatment can be appropriately selected from known methods.

After the surface treatment, solder can be formed on both pad layers. The method of forming solder can be appropriately selected from known methods such as screen printing, ball mounting, electroplating, and filling with molten solder after formation of a resist pattern. In the present embodiment, electroless Ni/Pd/Au plating is performed on both surfaces as the surface treatment, and solder is formed using ball mounting method on both surfaces. Thus, the interposer 100 of the present embodiment, in which the first connection terminals 16 and the second connection terminals 17 are formed on the first outer layer structure 5 and the second outer layer structure 11, respectively, can be obtained.

FIG. 10B shows a step of electrical inspection of the interposer 100, in which electrical inspection probes are simultaneously brought into contact with the first connection terminal 16 and the second connection terminal 17 on both surfaces of the interposer 100, respectively.

Details of the electrical inspection and the production procedure using the results are as follows:
1) a first inspection step of performing an electrical inspection of the interposer via the connection terminals,
2) a first determination step of determining whether the interposer is non-defective or defective based on the result of the first inspection step,
3) a preliminary connection step of mounting semiconductor devices on the interposer determined as “non-defective” in the first determination step,
4) a second inspection step of performing an electrical inspection of a semiconductor package preliminarily connected in the preliminary connection step,
5) a second determination step of determining whether the semiconductor package is non-defective or defective based on the result of the second inspection step, and
6) a repair step of repairing and/or replacing the mounting of the semiconductor devices determined as “defective” in the second determination step.

In addition to the above production procedure, the following procedure may be performed:
7) a third inspection step of performing an electrical inspection of the semiconductor package after the repair step,
8) a third determination step of determining whether the semiconductor package is non-defective or defective based on the result of the third inspection step, and
9) a fixing step of supplying an underfill into gaps between the semiconductor devices and the interposer of the semiconductor package determined as “non-defective” in the third determination step.

The physical requirements (e.g., degree of rigidity) for the feasibility of electrical inspection can be, for example, a physical characteristic value obtained from the relationship between the load (N) in a four-point bending test and the corresponding deflection (mm: displacement in the Z direction at the apex of the bend).

The physical requirements can also be determined by the elastic modulus of bending deformation (Δstress/Δstrain: stress per unit strain), according to the JIS standard JIS K 7017, or the like.

### Advantageous Effects of First Embodiment

As described above, the interposer 100 according to the present embodiment is sufficiently rigid to allow transport of the interposer alone, and since the first connection terminals 16 and the second connection terminals 17 are exposed on both surfaces of the interposer, the interposer 100 can be subjected to electrical inspection before semiconductor devices are mounted to determine whether the interposer itself is non-defective or defective. Therefore, only the interposers that are determined to be non-defective can be provided in the subsequent production process of semiconductor package, which contributes to improvement in SiP assembly yield.

FIG. 10C is a diagram showing that a panel substrate in which a plurality of interposers of the present embodiment are continuously formed in a matrix pattern is diced at the lines A-A into individual interposers. Thus, the interposers 100 of the present embodiment can be produced.

### Modifications of First Embodiment

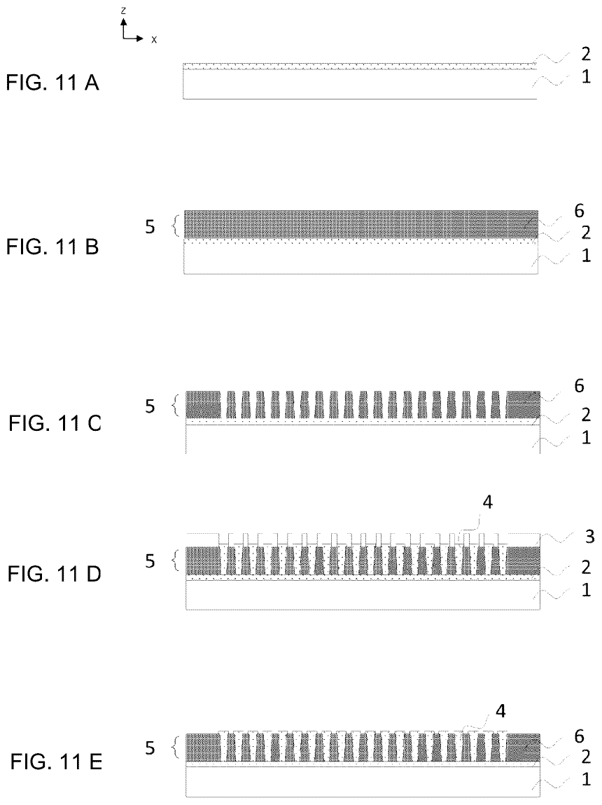

Next, with reference to FIGS. 11A to 11E, a production process of a modified example of the first embodiment will be described.

FIG. 11A shows that, similarly to FIG. 7A, a support substrate 1 is provided by disposing a laser release layer on a glass substrate, and disposing a metal layer 2 on the laser release layer. The metal layer 2 may be formed by electroless plating or sputtering, or a carrier copper foil may be formed as the metal layer 2 on a copper clad laminate (CCL) substrate with a prepreg therebetween.

Next, in FIG. 11B, a second insulating resin layer 6 constituting a first outer layer structure 5 is formed on the support substrate 1.

Then, as shown in FIG. 11C, vias for forming pads of the first outer layer structure 5 are formed by laser processing. After the vias are formed, a desmear treatment or the like may be performed as appropriate.

Then, as shown in FIG. 11D, a metal layer (not shown) is formed on the entire surface including the inside of the vias, and a resist pattern 3 is formed. Then, electrolytic plating is performed to fill the vias with metal and thus conductive members 4 are formed.

Next, FIG. 11E shows that the photoresist has been removed, and then the exposed unnecessary metal layer has been removed by etching to obtain the first outer layer structure 5.

In this modified example, the first outer layer structure formed of a single layer has been described. However, it is also possible to form a first outer layer structure formed of multiple layers as shown in FIG. 5 by the method of this modified example.

### (Method of Assembling Semiconductor Device)

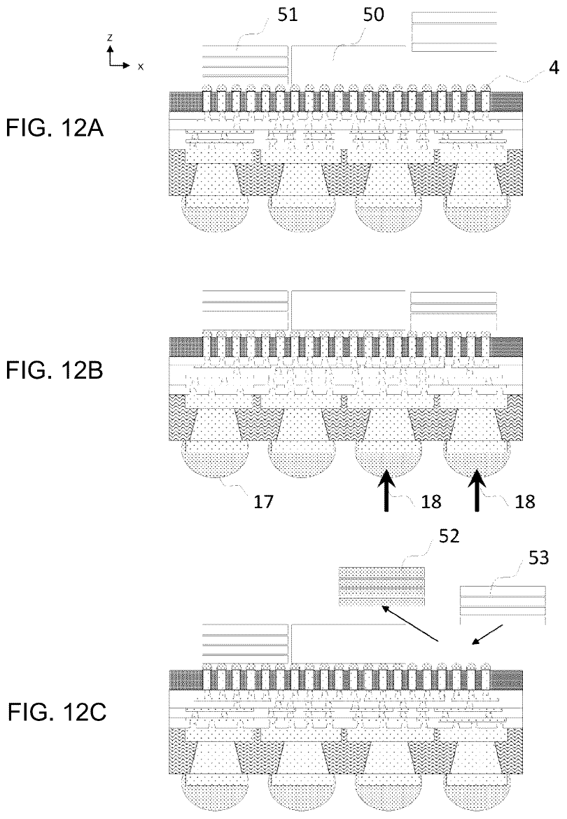

Next, with reference to FIGS. 12A-12C, a method of mounting semiconductor devices on the interposer of the present embodiment to form a semiconductor package will be described.

FIG. 12A is a schematic cross-sectional diagram of a step of mounting semiconductor devices 50 and 51 on the interposer to form a semiconductor package. The interposer used in the present embodiment is an interposer that has undergone an electrical inspection on the interposer alone and determined to be non-defective.

Examples of the method of mounting semiconductor devices include known mounting methods such as mass reflow and thermo-compression bonding (TCB). Using TCB reduces occurrence of positional deviation of a plurality of semiconductor devices during mounting or reflow and CTE mismatch due to high temperature heating of the interposer.

Further, in the underfill step of the present embodiment, it is preferred to use capillary underfill rather than non-conductive films (NCF) and non-conductive pastes (NCP). The reason for using capillary underfill is that, if a defect is found in a semiconductor device in the subsequent electrical inspection, the defective semiconductor device can be easily replaced.

FIG. 12B is a diagram showing an electrical inspection of SiP as a semiconductor package in the present embodiment. In the electrical inspection, an inspection probe 18 is brought into contact with the second connection terminal 17 to inspect the “mounting yield (Y_{ASSEMBLY})” including the individual semiconductor devices mounted and identify mounting defects or semiconductor device defects.

FIG. 12C is a schematic cross-sectional diagram showing a step of removing a part of the semiconductor device 52 having a mounting defect or a defective semiconductor device 52 identified in the previous step and replacing it with a non-defective semiconductor device 53. In the present embodiment, since the mounted semiconductor devices are not chip-fixed with a molding resin or underfill, the portions of mounting defect or defective semiconductor devices can be partially repaired. After the repair, (Y_{ASSEMBLY})=100% represented by formula (4) can be achieved.

Thus, the interposer according to the present embodiment can contribute to improvement in total yield of SiP assembly (Y_{TOTAL}) regardless of the number N of chips to be integrated. The repair can be performed by reversing the steps of TCB mounting.

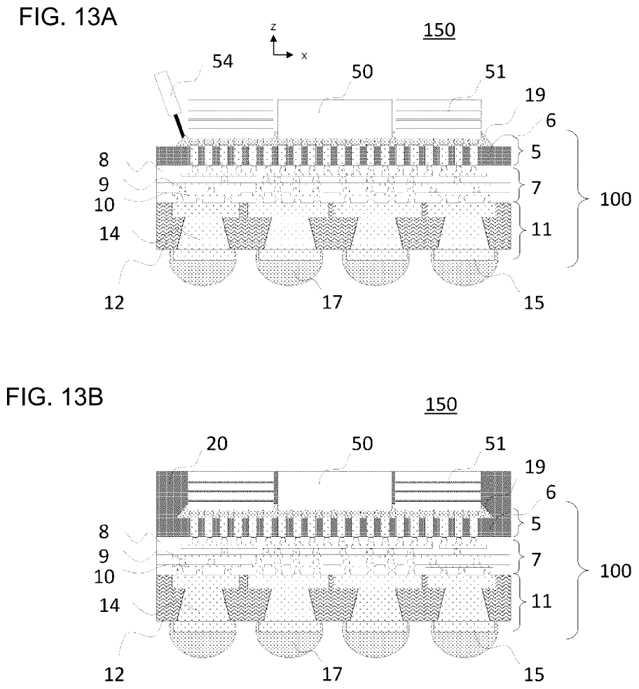

FIG. 13A is a diagram showing a capillary underfill step of forming an underfill 19 using an underfill supplying device 54 in a semiconductor package 150 of the present embodiment on which a plurality of semiconductor devices are mounted. After the inspection and repair, the semiconductor devices can be fixed to the interposer of the present embodiment using the underfill 19.

FIG. 13B is a schematic cross-sectional diagram showing that a molding resin 20 is further formed on the semiconductor devices. This fixing step using the molding resin is not necessarily required. The fixation with a molding resin can be appropriately selected from known methods. Furthermore, the upper surface of the molding resin 20 can be polished to expose the upper end of the semiconductor device.

As described above, through FIG. 12A to FIG. 13A or 13B, the semiconductor package 150 on which semiconductor devices are mounted can be produced. According to the present embodiment, due to the interposer being provided as an independent unit, the following advantages are obtained.
1) The interposers with an inspection guarantee of (Y_{INTERPOSER})=100% can be used in the mounting step. Further, repair recovery can make the yield closer to (Y_{ASSEMBLY})=100%. Accordingly, the total yield of SiP assembly can be improved.
2) Since the FC-BGA substrate and the interposer 100 are independent, it is possible to mount semiconductor devices on the interposer to form a semiconductor package, which can then be mounted on the FC-BGA substrate or motherboard, or to mount semiconductor devices after the interposer is mounted on the FC-BGA substrate or motherboard, which improves the degree of freedom in the production process.
3) Regarding the CTE of each component, since the interposer can have an intermediate value between the semiconductor device and the FC-BGA substrate, the semiconductor devices can be first assembled to the interposer, which can then be mounted on the BGA substrate, to thereby mediate the matching of the CTEs of the semiconductor devices and the FC-BGA substrate, which contributes to improvement in connection reliability.
4) It is also possible to appropriately select the form in which the motherboard is directly connected without using an FC-BGA substrate.

### Second Embodiment

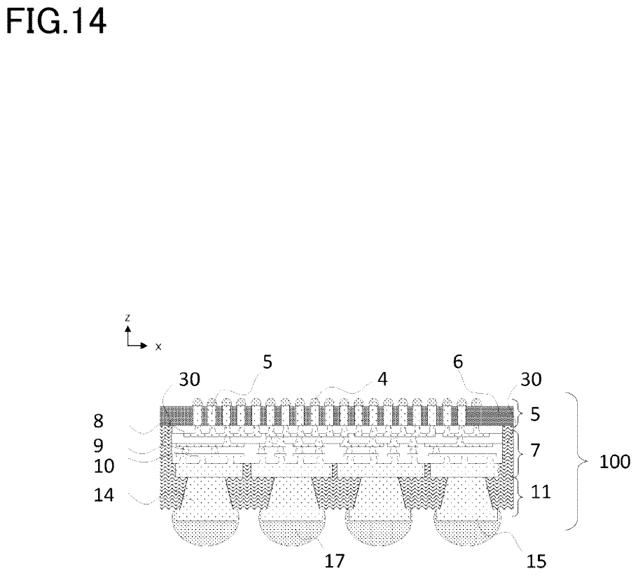

Next, with reference to FIG. 14, a second embodiment will be described. FIG. 14 is a schematic cross-sectional diagram of an interposer 100 of a second embodiment. The second embodiment differs from the first embodiment in that the area where the inner layer structure 7 is formed is smaller than those of the first outer layer structure 5 and the second outer layer structure 11, and the inner layer structure 7 is not exposed on the side surface of the interposer. That is, in the interposer 100 of the second embodiment, the side surface of the inner wiring layer is enclosed by the second outer layer structure 11.

### Production Method of Second Embodiment

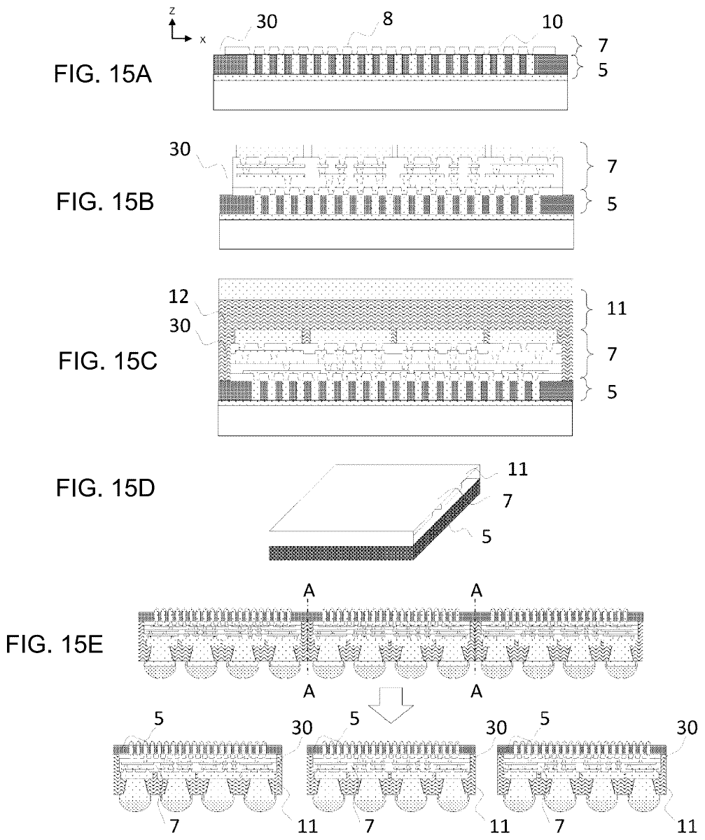

Next, with reference to FIGS. 15A-15E, a production method of the second embodiment will be described. In the following description, components that are the same or equivalent to those in the first embodiment described above are denoted by the same reference signs, and the description thereof will be simplified or omitted, and only the differences from the first embodiment will be described.

The first half of the production method of the second embodiment can be the same steps as those shown in FIGS. 7A to 7E in the production method of the first embodiment. In the following description, an interposer, a semiconductor package and a method of producing the same according to the second embodiment will be described referring to FIGS. 15A to 15E, focusing on the differences from the first embodiment.

FIG. 15A is a step corresponding to FIG. 7A. In the second embodiment, after the first insulating resin layer 8 of the inner layer structure 7 is formed on the first outer layer structure 5, the first insulating resin layer 8 on a side surface 30 of the interposer is removed while forming vias 9. The side surface 30 can be easily removed by development in photolithography.

FIG. 15B is a schematic diagram corresponding to FIG. 8D, in which the step of forming the inner wiring layer has been repeated three times. When the first insulating resin layer 8 is formed of a non-photosensitive insulating resin, the first insulating resin layer 8 on the side surface 30 may be removed collectively by laser ablation after a plurality of inner wiring layers are formed. Alternatively, an end portion of the insulating resin may be removed by half dicing.

Further, it may be removed by dry etching after the resist is formed or may be removed by wet etching by dissolving the resin. The method of removing the first insulating resin layer 8 on the side surface 30 is not limited to the methods described in the present embodiment, and known removal methods can be appropriately used.

FIG. 15C is a diagram showing a step corresponding to FIG. 8E. First, a prepreg and a copper foil with a carrier are formed on the upper side of the inner layer structure 7 with a lamination press to constitute the third insulating resin layer 12 of the second outer layer structure 11. In the second embodiment, the side surface 30 of the inner layer structure 7 is covered with the third insulating resin layer 12.

FIG. 15D is a schematic diagram of a three-dimensional view of the structure shown in FIG. 15C. The inner layer structure 7 has the area smaller than that of the first outer layer structure 5, and the second outer layer structure 11 is formed on the upper surface of the inner layer structure 7.

FIG. 15E is a diagram showing a step corresponding to FIG. 10C. In the second embodiment, dicing is performed at the lines A-A of FIG. 15E so that the inner wiring layer is covered with the third insulating resin layer 12 and not exposed on the side surface 30 of the interposer 100.

### Advantageous Effects of Second Embodiment

With this configuration, the side surface of the inner layer structure can be protected, further enhancing the rigidity of the interposer 100. Further, since all the surfaces of the inner structure are covered with the third insulating resin layer 12, the interposer 100 has higher resistance to stress distortion due to differences in CTE.

More specifically, since the first outer layer structure and the second outer layer structure are made of a material having high elasticity and low CTE with an elastic modulus of 5 GPa or less and a CTE of 20 ppm/° C. or less, the side surface of the inner wiring layer can be protected and reinforced. In particular, it is effective in suppressing cracking and interlayer delamination on the side surface 30 of the inner layer structure 7 due to thermal cycle stress.

### Third Embodiment

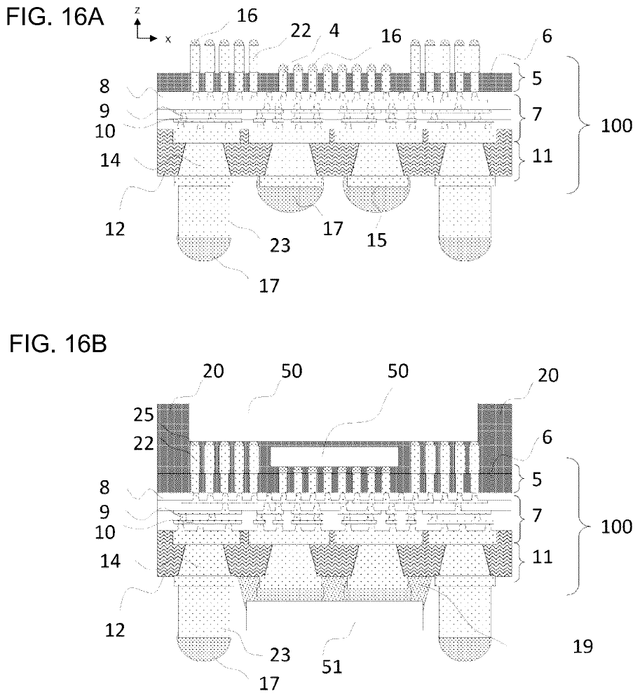

Next, with reference to FIGS. 16A and 16B, a third embodiment will be described. FIG. 16A is a schematic cross-sectional diagram of an interposer 100 of the third embodiment of the present embodiment. The third embodiment differs from the first embodiment in that the first outer layer structure 5 and the second outer layer structure 11 are provided with protruding electrodes.

In the following description, an interposer, a semiconductor package and a method of producing the same according to the third embodiment will be described referring to FIG. 16.

In the third embodiment, protruding electrodes 22 are formed on the upper side of the first outer layer structure 5, that is, on the upper side of the conductive members penetrating the first insulating resin layer, or protruding electrodes 23 are formed on the lower side of the second outer layer structure, that is, on the lower side of the conductive members penetrating the second insulating resin layer. By forming solder on the protruding electrodes 22 formed on the upper side of the first outer layer structure, external connection terminals of different heights can be formed in the respective first connection terminals and second connection terminals.

In the third embodiment, due to the first outer layer structure 5 and the second outer layer structure 11 formed on both surfaces of the inner layer structure 7, respectively, it is possible to transport the interposer alone during the production process even after it is separated from the support substrate. Also, since there is no support substrate, the protruding electrodes can be formed on both surfaces of the interposer.

Further, the method of forming the protruding electrodes 22 and 23 can be appropriately selected from known electrode forming methods.

FIG. 16B shows an example semiconductor package as an example of the third embodiment, in which semiconductor devices 50 and 51 are connected and mounted on both surfaces of the interposer 100, respectively. The formation of the external connection terminals having different heights enables mounting of the semiconductor devices 50 are 51 on both surfaces of the interposer, respectively, which improves the degree of freedom in mounting the semiconductor devices.

It goes without saying that the underfill 19 or the molding resin 20 may be formed on each of the semiconductor devices 50 and 51. The method of forming the underfill 19 or the molding resin 20 on the semiconductor devices or the structure thereof may be appropriately selected from known mounting methods.

### Production Method of Third Embodiment

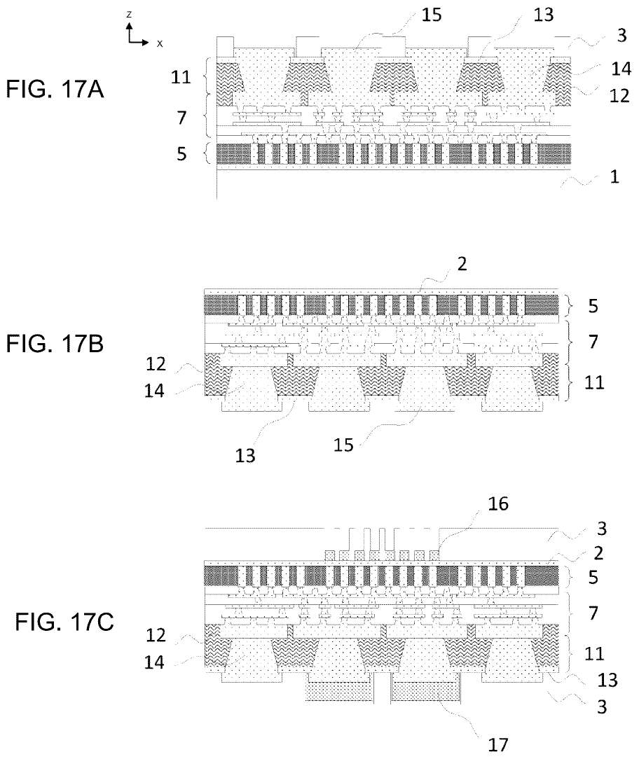

Next, with reference to FIGS. 17A-17C, a production method of a third embodiment will be described. In the following description, components that are the same or equivalent to those in the first embodiment described above are denoted by the same reference signs, and the description thereof will be simplified or omitted, and only the differences from the first embodiment will be described.

The first half of the production method of the third embodiment can be the same steps as those shown in FIGS. 7A to 9B in the production method of the first embodiment. In the following description, an interposer, a semiconductor package and a method of producing the same according to the third embodiment will be described referring to FIGS. 17A to 21, focusing on the differences from the first embodiment.

FIG. 17A corresponds to FIG. 8A of the first embodiment, and the steps up to this step can be the same as those in the first embodiment.

FIG. 17B is a cross-sectional diagram of the interposer 100 from which the resist 3 and the support substrate 1 shown in FIG. 17A have been removed. For convenience of illustration, FIG. 17B shows FIG. 17A upside down.

In FIG. 17B, the metal layer 2 and the thin copper foil 13 of a carrier copper foil are formed on the first outer layer structure 5 and the second outer layer structure 11, respectively.

Next, FIG. 17C is a diagram showing a step of forming the first connection terminals 16 and the second connection terminals 17. Subsequent to FIG. 17B, the resist pattern 3 can be formed on both of the metal layer 2 and the thin copper foil 13 of a carrier copper foil, and then electrolytic Ni plating and electrolytic Sn—Ag plating, which forms solder, can be performed to form the first connection terminals 16 and the second connection terminals 17. When the first connection terminals 16 on the first outer layer structure-side and the second connection terminals 17 on the second outer layer structure-side are desired to be formed with different thicknesses and volumes, different current values can be supplied to each of the seed layers to form desired shapes in the electrolytic plating step. Alternatively, in the step of FIG. 17B, a protective layer may be formed on one surface and the resist 3 may be formed on the other surface so that external connection terminals are formed on each surface at the same time. Alternatively, a resist pattern can be formed on both surfaces and then a protective sheet can be formed on one surface so that external connection terminals are formed by electrolytic plating on each surface at the same time. The electrolytic plating method and the resist pattern formation method can be appropriately selected from known pattern formation methods and are not limited to these described above. Further, the solder layer may be heated in a reflow furnace after this step to form rounded bumps.

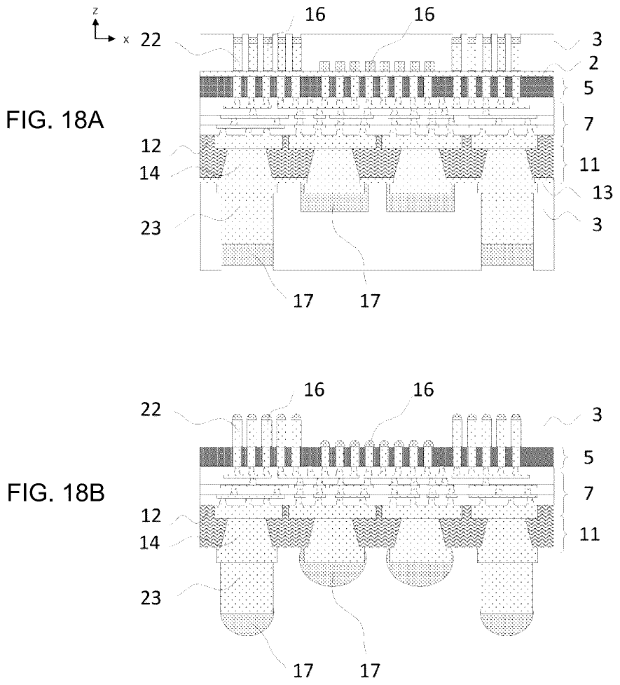

FIG. 18A is a diagram showing a step of forming protruding electrodes 22 and 23. After the step of FIG. 17C, the resist pattern is removed and a new resist pattern 3 is formed, and then electrolytic copper plating, electrolytic Ni plating or electrolytic Sn—Ag plating can be performed to form protruding electrodes 22 and 23.

If the first connection terminals 16 and the protruding electrodes 22 on the first outer layer structure-side and the second connection terminals 17 and the protruding electrodes 23 on the second outer layer structure-side are desired to be formed with different thicknesses and volumes, different current values are supplied to each of the seed layers to form desired shapes in the electrolytic plating step. If the thickness and volume are desired to be significantly different, a resist pattern can be formed on both surfaces and then a protective sheet can be formed on one surface so that external connection terminals are formed by electrolytic plating on each surface at the same time. The electrolytic plating method and the resist pattern formation method can be appropriately selected from known pattern formation methods and are not limited to these described above. Further, the solder layer may be heated in a reflow furnace after this step to form rounded bumps.

FIG. 18B is a diagram showing the interposer 100 according to the third embodiment. After the resist 3 of the substrate in FIG. 18A is removed, the metal layer 2 and the thin copper foil layer of the carrier copper foil are removed by etching. Further, the solder layer is heated in a reflow furnace to form round bumps, whereby the interposer 100 of the third embodiment can be obtained.

### Advantageous Effects of Third Embodiment

According to the interposer of the third embodiment, as will be described later in the fourth embodiment, the semiconductor devices can be stacked and mounted on the upper side of the first outer layer structure 5 using steps formed by the protruding electrodes, which further improves the integration ratio of the SiP.

### Fourth Embodiment

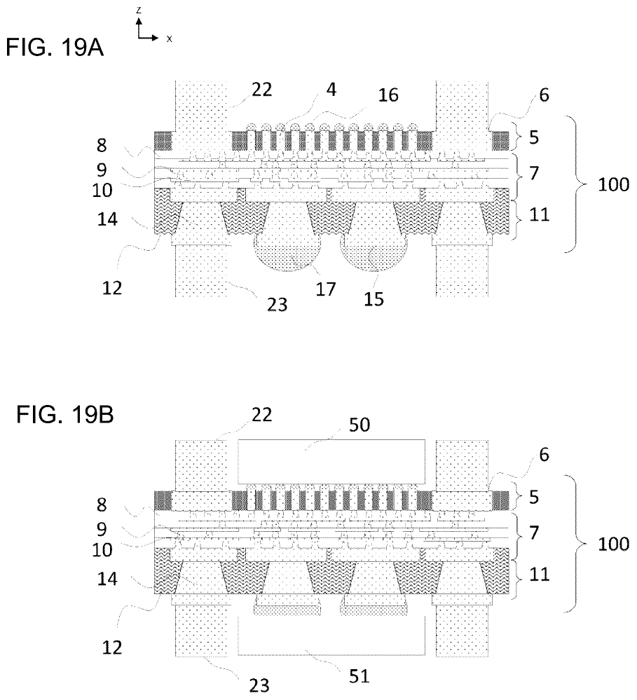

Next, with reference to FIG. 19, a fourth embodiment will be described. The fourth embodiment is a semiconductor package in which semiconductor devices are mounted on the interposer of the third embodiment. The fourth embodiment differs from the first embodiment in that semiconductor devices can be stacked and mounted on the upper side of the first outer layer structure 5 and the lower side of the second outer layer structure 11 using the protruding electrodes of the third embodiment.

Also, the fourth embodiment further differs from the first embodiment in that the interposers 100 can be stacked on one another using the protruding electrodes.

FIG. 19A show a fourth embodiment of the interposer according to the present invention. FIG. 19A differs from the third embodiment shown in FIG. 18A in that the first connection terminals 16 and the second connection terminals 17 are not formed by electrolytic Ni and electrolytic Sn—Ag plating on the protruding electrodes 22 and 23.

FIG. 19B shows a step after the semiconductor devices 50 and 51 are mounted on the first connection terminals 16 and the second connection terminals 17 that do not form the protruding electrodes in the interposer 100 of the fourth embodiment.

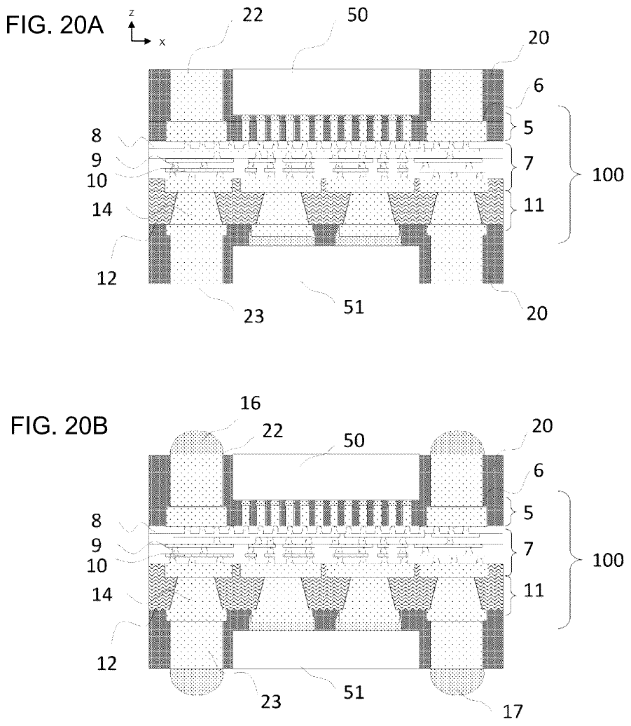

Further, FIG. 20A shows a semiconductor package according to the present embodiment in which a molding resin is formed on both surfaces of the interposer of FIG. 19B on which the semiconductor devices are mounted.

FIG. 20B is a diagram of the semiconductor package shown in FIG. 20A in which the molding resin formed on the outermost surface of the semiconductor package has been ground to expose the surfaces of the protruding electrodes 22 and 23 and semiconductor devices 50 and 51.

The exposed protruding electrodes 22 and 23 have been subjected to surface treatment, and the first connection terminals 16 and the second connection terminals 17 have been formed thereon.

Then, Ni/Pd/Au plating is performed as a surface treatment on the first connection terminals 16 and the second connection terminals 17, and then solder ball mounting and reflowing are performed to complete the first connection terminals 16 and the second connection terminals 17 on each surface at the same time.

Further, the type and method of surface treatment, the composition and type of solder and the method of forming solder can be appropriately selected from known treatment methods.

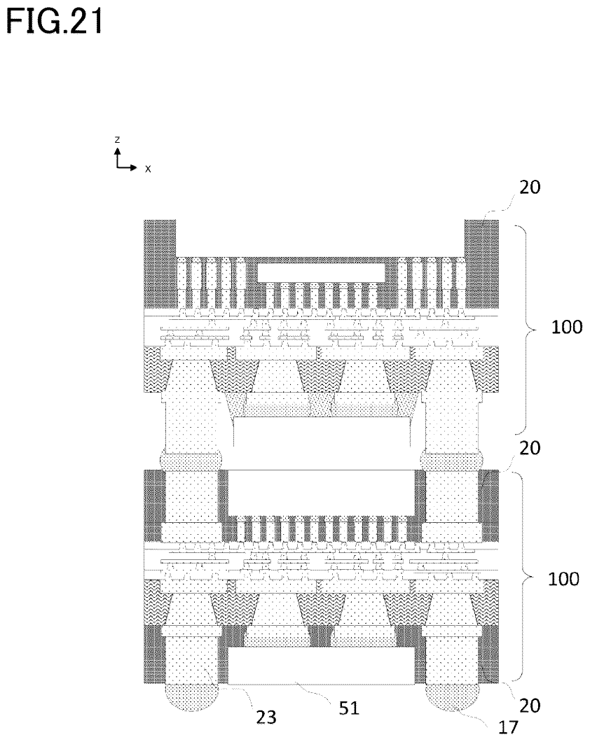

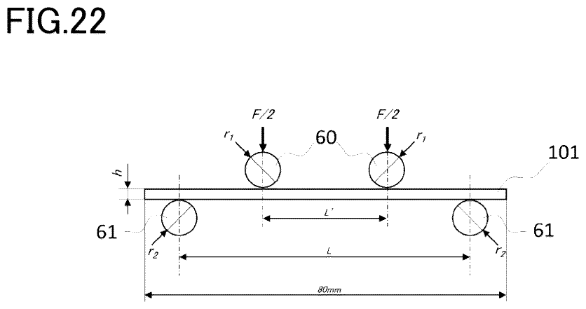

FIG. 21 is a diagram showing an example semiconductor package in which a plurality of semiconductor packages are stacked.

FIG. 21 shows a semiconductor package in which the semiconductor package (upper layer) of the third embodiment shown in FIG. 16B is stacked on the semiconductor package (lower layer) shown in FIG. 20B.

Further, such stacking of interposers and staking of semiconductor devices are not limited to the combinations described above, and any number of stacks can be formed as long as processing is physically possible, and also it goes without saying that the type of the semiconductor devices and interposers to be combined can be arbitrarily selected.

As described above, the interposer of the present embodiment can be used to realize interposer stacking structures, which contributes to improvement in functionality of semiconductor packages using advanced SiP.

### Advantageous Effects of Fourth Embodiment

As described above, by using an interposer that can be independently transported without a support during the production process, the protruding electrodes can be formed on both surfaces of the interposer, and these protruding electrodes can be used to form connection terminals having steps on both surfaces of the interposer. As a result, it is possible to mount a plurality of semiconductor devices on both surfaces of the interposer, and it is also possible to connect such interposers to each other, significantly improving the integration and functionality of the SiP.

### Fifth Embodiment

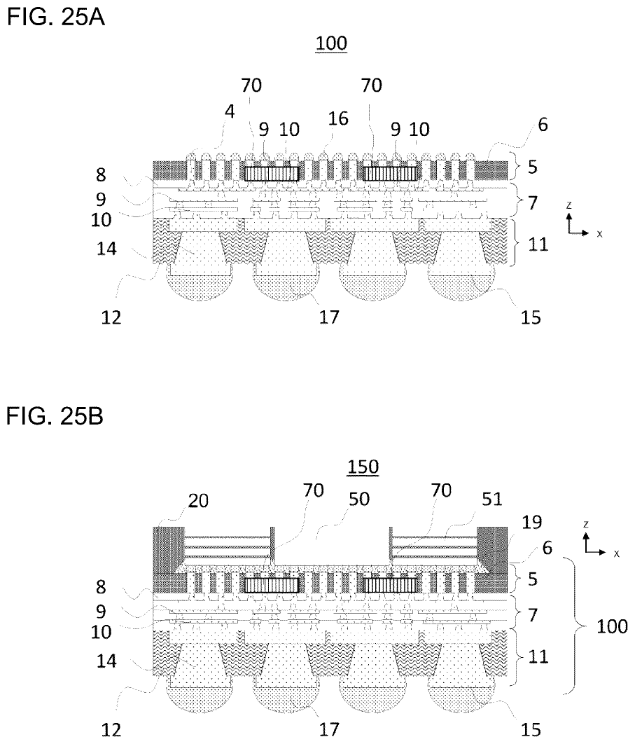

Next, with reference to FIGS. 25A and 25B, a fifth embodiment will be described.

FIG. 25A is a schematic cross-sectional diagram of an interposer 100 of the fifth embodiment in which built-in components 70 are embedded in the interposer 100.

FIG. 25B is a schematic cross-sectional diagram of a semiconductor package 150 in which semiconductor devices 50 and 51 are mounted on the interposer 100 of the fifth embodiment.

The fifth embodiment differs from the first embodiment in that the built-in components 70 are embedded.

The built-in components 70 may be electrically connected to the first connection terminals 16 provided on the upper surface of the interposer. Alternatively, when built-in component connection terminals (not shown) are provided on the lower surface of the built-in components 70, these may be electrically connected to the first connection terminals 16 or the second connection terminals 17 via the vias 9 and the wiring 10 of the inner layer structure 7.

Alternatively, when connection terminals are provided on both upper and lower surfaces of the built-in components 70, these may be electrically connected to both connection terminals at the same time.

The size of the built-in components 70 is preferably at least smaller than that of the area of the interposer 100 and does not restrict mounting of semiconductor devices and wire routing, but is not limited by the present embodiment.

The number of embedded built-in components 70 preferably does not restrict mounting of semiconductor devices and wire routing but is not limited by the present embodiment.

The thickness of the built-in components 70, at least when incorporated in the interposer 100, is preferably smaller than that of the interposer. The thickness preferably does not restrict mounting of semiconductor devices and wire routing but is not limited by the present embodiment.

For example, the thickness of the built-in component 70 is preferably 10 μm or greater and 1 mm or less.

If the thickness of the built-in components 70 is less than 10 μm, not only may the interposer itself be insufficiently rigid, but the built-in components may be damaged even when rigid materials are used.

If the thickness of the built-in components 70 is greater than 1 mm, the interposer itself needs to be thicker, which not only increases the production time and cost, but also makes it difficult to incorporate them in the interposer.

The built-in components 70 may be selected from silicon, ceramic, glass and compound semiconductor-based components.

Examples of the silicon-based components include semiconductor chips having capacitors, inductors, chip components having re-wiring functions, and computing functions on a silicon wafer.

Further, the silicon-based components may be functional modules including one or more of these elements.

Examples of the ceramic-based components include components having independent functions, such as capacitors, inductors and wiring.

Further, the ceramic-based components may be functional modules including one or more of these elements.

Furthermore, examples of the ceramic materials include alumina, yttria, cordierite, cermet, sapphire, zirconia, steatite, forsterite, silicon carbide, aluminum nitride, silicon nitride and low temperature co-fired ceramics (LTCC), but other materials may also be used.

Examples of the glass-based components include components having independent functions, such as capacitors, inductors and wiring.

Further, the glass-based components may be functional modules including one or more of these elements.

Examples of the glass material include soda-lime glass, borosilicate glass, crystallized glass and quartz glass, but other materials may also be used.

Examples of the compound semiconductor-based components include high-frequency devices and optical semiconductors containing compound semiconductors such as GaAs, InP and InGaAlP, LEDs and laser diodes containing InGaN, and power semiconductor materials such as SiC and GaN, but other materials may also be used.

As shown in Table 1, typical insulating resin materials have a coefficient of linear thermal expansion (CTE) in the range of 30 to 100 ppm/K and an elastic modulus in the range of 1 to 30 GPa.

On the other hand, silicon, ceramic, glass and compound semiconductor materials have a CTE of 12 ppm/K or less and an elastic modulus in the range of 60 to 470 GPa, which are lower thermal expansion and higher elasticity than the insulating resin materials.

Accordingly, incorporating the components in the interposer 100 makes it possible to impart both high thermal dimensional stability and rigidity to the interposer 100.

The thermal dimensional stability refers to the property of the interposers to resist thermal deformation due to thermal cycling.

TABLE 1

| | | | Elastic |
|---|---|---|---|
| | | | modulus |
| Type | Material | CTE | (GPa) |
| Silicon | Silicon wafer | 3 | 170 |
| Ceramic | Alumina | 7.2 | 360 |
| | Yttria | 7.2 | 160 |
| | Sapphire | 7.7 | 470 |
| | Silicon carbide | 3.7 | 440 |
| | Aluminum nitride | 4.6 | 320 |
| | Silicon nitride | 2.8 | 300 |
| | LTCC | 3.4-12 | 74-128 |
| Glass | Soda-lime glass | 9 | 72 |
| | Borosilicate | 3.3 | 73 |
| | Crystallized glass | −0.6 | 84-95 |
| | Quartz glass | 0.59 | 74 |
| Compound | GaAs | 5.7 | 83 |
| semiconductor | InP | 4.6 | 60 |

| | | |
|---|---|---|
| Insulating resin material | 30-100 | 1-30 |

### Production Method of Fifth Embodiment

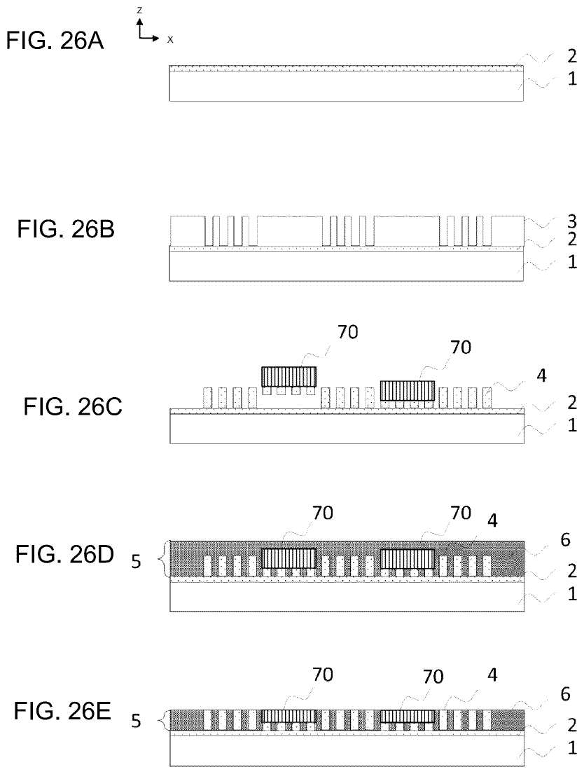

Next, with reference to FIGS. 26A-26E, a method of producing an interposer 100 of the fifth embodiment shown in FIG. 25A will be described.

In the following description, components that are the same or equivalent to those in the first embodiment or the like described above are denoted by the same reference signs, and the description thereof will be simplified or omitted, and only the differences from the first embodiment or the like will be described.

FIG. 26A is a step corresponding to FIG. 7A of the first embodiment.

In the fifth embodiment, first, a support substrate is prepared as in FIG. 26A. The support substrate can be the same as that described in the first embodiment.

FIG. 26B is a diagram showing a step of forming a resist pattern 3 in portions other than the portions on which built-in components 70 are to be mounted.

As shown in FIG. 26B, the resist pattern 3 is formed in portions other than the portions on which the built-in components 70 are to be mounted. In this example, a liquid resist is formed at 120 μm, and apertures are formed so that cylinder pads can be formed at the same pitch and the same diameter as in the first embodiment.

FIG. 26C is a diagram showing that, after conductive members 4 are formed by electrolytic copper plating at an average thickness of 120 μm, the resist pattern 3 is removed and built-in components 70 are mounted.

In the present embodiment, silicon capacitors are mounted as built-in components 70.

Further, the silicon capacitors may have, for example, a total thickness of 120 μm and a size of 5 mm×5 mm.

In the present embodiment, the silicon capacitors are fixed to the support substrate via an adhesive, but other fixation methods can also be used.

FIG. 26D is a step corresponding to FIG. 7D.

FIG. 26D is a diagram showing a step of forming a second insulating resin layer 6 constituting a first outer layer structure 5 by vacuum lamination using a 150 μm-thick film of molding resin.

In the present embodiment, the second insulating resin layer 6 is formed by vacuum lamination using a 150 μm-thick film of molding resin.

FIG. 26E is a diagram showing a step of polishing the molding resin and the Si substrate of the silicon capacitor using a grinder to expose a part of the built-in components 70 and the conductive members 4.

In the step of FIG. 26E, the molding resin and the Si substrate of the silicon capacitor are polished with a grinder to expose a part of the built-in components 70 and the conductive members 4.

In the present embodiment, the second insulating resin layer 6 constituting the first outer layer structure 5 is polished to adjust the first outer layer structure 5 to 100 μm.

The method of exposing a part of the built-in components 70 and the conductive members 4 is not limited to the methods of the present embodiment, and similarly to FIG. 7, known methods such as grinder polishing, buff polishing, belt polishing, flycutting and CMP may be used. Thus, in the present embodiment, the conductive members 4 are formed as the pads in the second insulating resin layer 6 of the first outer layer structure 5.

Thereafter, an inner layer structure 7 is formed in the same manner as described in FIGS. 8A to 8D in the first embodiment, a second outer layer structure 11 is formed in the same manner as described in FIGS. 8E to 9C, and first connection terminals 16 and second connection terminals 17 are formed in the same manner as described in FIG. 9D to FIG. 10C, whereby an interposer 100 of the modified example shown in FIG. 25A can be formed.

Further, the method of inspection, the method of assembling a semiconductor device and the method of repair in FIGS. 12A to 13B in the first embodiment can be used to produce a semiconductor package 150.

### Modified Example 1 of Fifth Embodiment

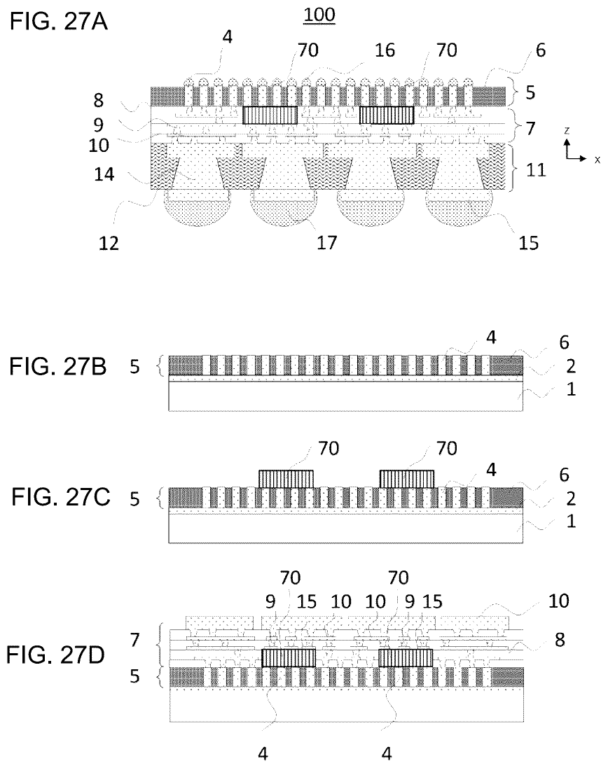

An interposer 100 shown in FIG. 27A is a diagram of a modified example of the fifth embodiment, in which built-in components 70 are accommodated on the lower surface of the first outer layer structure 5 inside the inner layer structure 7.

The interposer 100 of FIG. 27A is produced by the same steps as in FIGS. 7A to 7E of the first embodiment, and thus the first outer layer structure 5 shown in FIG. 7E is formed.

To assist explanation, FIG. 7E should be referred to with FIG. 27B, and subsequent steps will be described below.

The built-in components 70 are mounted as shown in FIG. 27C on the second insulating resin layer 6 shown in FIG. 27B to be electrically connected to the conductive members 4.

The mounting method may be formation of a conductive paste on the terminals or solder connection. Alternatively, an underfill may be provided in gaps between the built-in components 70 and the first outer layer structure 5. Then, a substrate shown in FIG. 27D in which four layers of the inner layer structure 7 are formed is obtained by the same method as in FIGS. 8A to 8D of the first embodiment.

The built-in components 70 shown in FIG. 27D may be electrically connected to the first connection terminals via the conductive members 4. Alternatively, when connection terminals (not shown) are provided on the upper surface of the built-in components 70 shown in FIGS. 27C and 27D, the connection terminals (not shown) on the upper surface of the built-in components 70 may be electrically connected to the wiring 10 of the inner layer structure via the pads 15 and the vias 9 as shown in FIG. 27D after the steps shown in FIGS. 8A to 8D of the first embodiment, and thus electrically connected to the first and second connection terminals.

Alternatively, when connection terminals are provided on both upper and lower surfaces of the built-in components 70, these may be electrically connected to both connection terminals at the same time.

### Modified Example 2 of Fifth Embodiment

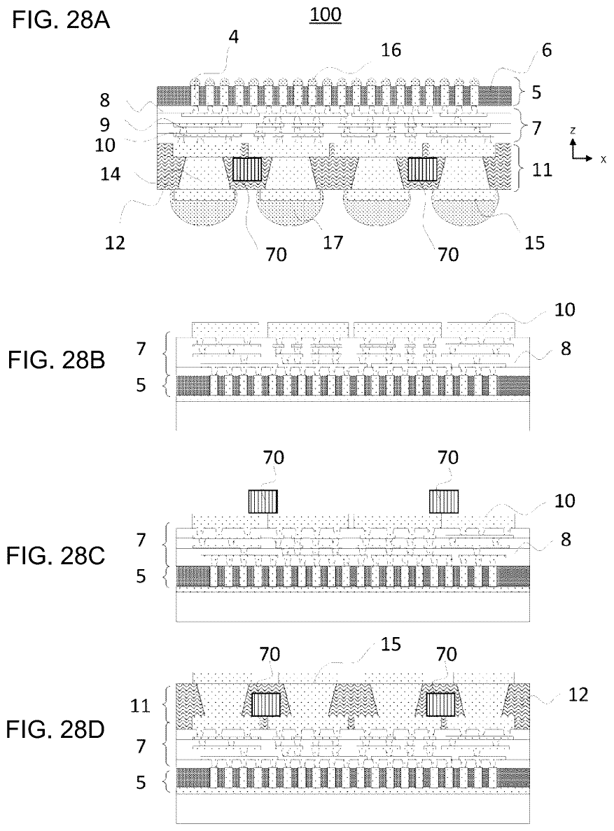

An interposer 100 shown in FIG. 28A is a modified example in which built-in components 70 are accommodated inside the second outer layer structure 11.

The interposer 100 of FIG. 28A is produced by the same steps as in FIGS. 7A to 7E and FIGS. 8A to 8D of the first embodiment.

To assist explanation, FIG. 8D should be referred to with FIG. 28B, and subsequent steps will be described below.

FIG. 28B is a diagram after four layers of the inner layer structure 7 is formed as in FIG. 8D of the first embodiment.

Next, as shown in FIG. 28C, the built-in components 70 are mounted on a part of the wiring 10. The mounting method is not limited by this modified example. For example, formation of a conductive paste on the terminals or solder connection may be used.

Next, FIG. 28D is a diagram showing that the steps of FIGS. 8E to 9C of the first embodiment have been performed. Furthermore, the interposer 100 of this modified example shown in FIG. 28A can be formed by the same method as in FIGS. 9D to 10C.

The fifth embodiment in the present invention shown in FIG. 25A and the modified examples thereof shown in FIGS. 27A and 28A may be combined with the modified example shown in FIG. 4 in which the first connection terminals 16 and the second connection terminals 17 on both surfaces are partitioned by a solder resist.

Further, these may be combined with a structure shown in FIG. 5 in which two or more layers of the first outer layer structure 5 are formed.

Furthermore, these may be combined with a structure shown in FIG. 6 in which two or more layers of the second outer layer structure 11 are formed.

Furthermore, the method for forming vias in the first outer layer structure 5 by laser processing in the production method shown in FIG. 11 may be adopted.

The methods in the first to fourth embodiments in the present invention may be combined with the fifth embodiment in this modified example.

The above combinations of the modified examples and embodiments in the present invention can be appropriately implemented within the scope of the present invention.

### Advantageous Effects of Invention in Fifth Embodiment

According to the interposer 100 of the present embodiment, components based on rigid materials are incorporated in the interposer, contributing to improvement in independence of the interposer 100.

This improves the rigidity of the interposer 100 while making it possible to impart the functions of the built-in components to the interposer only having a function of re-wiring, contributing to improvement in functionality.

According to the interposer 100 of the present embodiment, the built-in components can be mounted in close proximity to the semiconductor devices, which is effective in reducing signal and power supply noise, stabilizing power supply to the chips, and the like. Alternatively, it is possible to incorporate optical semiconductor components in proximity to the semiconductor devices, which can be applied to package substrates and the like that combine optical transmission and electrical transmission.

### Summary of Effects of Embodiments

According to the embodiments of the present disclosure, providing an interposer having no support and capable of being transported as an independent unit has the following five effects.
1) Since the interposer itself has no support substrate and sufficient rigidity to undergo electrical inspection, electrical inspection guarantee of the interposer itself is possible at the stage before semiconductor devices are mounted. Accordingly, it is possible to prevent occurrence of defective semiconductor packages caused by mounting expensive semiconductor devices on defective interposers.
2) Due to the interposer having no support and being capable of being transported as an independent unit, it is possible to form external connection terminals with different heights on both surfaces of the interposer. Accordingly, a plurality of semiconductor devices can be stacked on both surfaces of the interposer, improving the degree of freedom in mounting, such as integration of semiconductor packages. As a result, it contributes to advanced SiP integration.
3) Electrical inspection of the interposer itself can be performed, so that if a defect is found in a semiconductor package, maximum relief can be achieved by repairing or replacing the mounting of the semiconductor devices without discarding non-defective interposers or semiconductor devices, thus significantly reducing the overall production cost.
4) The effects of the above 1) and 3) can greatly contribute to improvement in yield of SiP assembly, which integrates a plurality of semiconductor devices.
5) Since the interposer of the present disclosure can be provided independently of a support or FC-BGA substrate, the semiconductor package can be mounted on the FC-BGA substrate or motherboard, significantly improving the degree of freedom in mounting.

The embodiments of the present invention have been described, but the present invention is not limited to the above-mentioned embodiments, and various modifications can be made without departing from the spirit of the present invention.

For example, in the above embodiments, the first outer layer structure is formed before the second outer layer structure is formed, but the order of formation is not limited in any way, and the second outer layer structure (on the side connected to a BGA substrate or motherboard) may be first formed on the support substrate, and then the first outer layer structure may be formed.

Further, in FIGS. 7A to 10B, which show an outline of the production method of the interposer of the present embodiment, only one interposer is shown for convenience of illustration. However, it goes without saying that the production method of the present disclosure may also be performed in a state in which a plurality of interposers are arranged on a rectangular panel or a circular wafer.

In addition, the shape of the production panel or the thickness and size of the support substrate described in the present disclosure are not limited in any way, and appropriate shapes and sizes can be adopted.

The present invention can also have the following aspects.

### Aspect 1

An interposer including:
an inner layer structure including at least one inner wiring layer;
a first outer layer structure disposed on a first surface of the inner layer structure, the first outer layer structure having rigidity higher than that of the inner layer structure; and
a second outer layer structure disposed on a second surface of the inner layer structure, the second outer layer structure having rigidity higher than that of the inner layer structure, wherein
the first outer layer structure covers at least the first surface of the inner layer structure,
the second outer layer structure covers at least the second surface of the inner layer structure,
the inner wiring layer includes wiring disposed on a surface of a first insulating resin layer, which is a photosensitive insulating resin, and a conductive member penetrating the first insulating resin layer and connected to the wiring,
the first outer layer structure includes a second insulating resin layer and a conductive member penetrating the second insulating resin layer,
the second outer layer structure includes a third insulating resin layer and a conductive member penetrating the third insulating resin layer,
the second insulating resin layer is a non-photosensitive resin containing a filler and no fiber substrate,
the third insulating resin layer is a non-photosensitive resin containing a filler and a fiber substrate, and
the first outer layer structure and/or the second outer layer structure includes a terminal connectable to a semiconductor device on a surface opposite to that connected to the inner layer structure, the terminal being capable of being subjected to electrical inspection.

### Aspect 2

The interposer according to aspect 1, wherein
in the wiring of the inner layer structure including at least one inner wiring layer, the wiring formed on an outermost layer on the second surface of the inner layer structure has a thickness of at least 1.5 times a thickness of the wiring formed inside the inner wiring layer.

### Aspect 3

The interposer according to aspect 1 or 2, wherein
a specimen of the interposer has a load/deflection ratio measured by the following measurement method of 0.125 N/mm or greater:

### <Measurement Method>

a four-point bending test is performed on a horizontal surface of a specimen having dimensions of 80 mm length×15 mm width×h mm height (thickness of specimen) under conditions of a distance between supports L of 66 mm, an indenter radius r1 of 2 mm, and a distance between indenters of L′ of 22 mm at a test speed V calculated by the following formula:

$$\begin{matrix}[ Math . 1 ] & \\ V & ( 5 )\end{matrix}$$

$${ε}_{f}^{′} : strain rate [ 1 / min ]$$

### Aspect 4

The interposer according to any one of aspects 1 to 3, wherein
the second and third insulating resin layers have physical properties of an elastic modulus of 5 GPa or greater and a CTE of 20 ppm or less,
the third insulating resin layer is formed of a prepreg,
the second insulating resin layer is formed of a built-up resin or a molding resin, and
a sum of thicknesses of the first outer layer structure and the second outer layer structure is greater than a thickness of the inner layer structure.

### Aspect 5

The interposer according to any one of aspects 1 to 4, wherein
either the first outer layer structure or the second outer layer structure further covers a side surface of the inner layer structure.

### Aspect 6

The interposer according to any one of aspects 1 to 5, further including
a built-in component embedded in the interposer, the built-in component being based on silicon, ceramic, glass or compound semiconductor, wherein
the first outer layer structure or the second outer layer structure includes a terminal electrically connected to the built-in component.

### Aspect 7

A semiconductor package in which a semiconductor device is mounted on the interposer according to any one of aspects 1 to 6.

### Aspect 8

The semiconductor package according to aspect 7, wherein
a semiconductor device mounted on a connection terminal formed on a protruding electrode and a semiconductor device mounted on a connection terminal that does not form a protruding electrode are stacked and mounted.

### Aspect 9

The semiconductor package according to aspect 7 or 8, wherein
a plurality of the semiconductor packages are connected by the protruding electrode, and stacked.

### Aspect 10

A method of producing the interposer according to any one of aspects 1 to 6, the method including:
a first step of forming a first outer layer structure on a support substrate;
a second step of forming an inner layer structure on an upper side of the first outer layer structure;
a third step of forming a second outer layer structure on a upper side of the inner layer structure;
a fourth step of releasing the first outer layer structure from the support substrate; and
a fifth step of forming a connection terminal on outermost layers of the first outer layer structure and second outer layer structure, wherein
the method further includes a step of mounting a built-in component.

### Aspect 11

A method of producing a semiconductor package, the method including:
a first inspection step of performing an electrical inspection via a connection terminal;
a first determination step of determining whether the interposer is non-defective or defective based on a result of the first inspection step;
a preliminary connection step of mounting a semiconductor device on the interposer determined as “non-defective” in the first determination step;
a second inspection step of performing an electrical inspection of a semiconductor package preliminarily connected;
a second determination step of determining whether the semiconductor package is non-defective or defective based on a result of the second inspection step;
a repair step of repairing and/or replacing the mounting of the semiconductor device determined as “defective” in the second determination step;
a third inspection step of performing an electrical inspection of the semiconductor package after the repair step;
a third determination step of determining whether the semiconductor package is non-defective or defective based on a result of the third inspection step; and
a fixing step of supplying an underfill into a gap between the semiconductor device and the interposer of the semiconductor package determined as “non-defective” in the third determination step.

### REFERENCE SIGNS LIST

1: Support substrate; 2: Metal layer; 3: Resist pattern; 4: Conductive member; 5: First outer layer structure; 6: Second insulating resin layer; 7: Inner layer structure; 8: First insulating resin layer; 9: Via; 10: Wiring; 11: Second outer layer structure; 12: Third insulating resin layer; 13: Thin copper foil; 14: Via; 15: Pad; 16: First connection terminal; 17: Second connection terminal; 18: Inspection probe; 19: Underfill; 20: Molding resin; 21: Solder resist; 22: Protruding electrode; 23: Protruding electrode; 30: Side surface of interposer; 50, 51, 52, 53: Semiconductor device; 54: Underfill supplying device; 60: Indenter; 61: Support; 70: Built-in component; 100: Interposer; 150: Semiconductor package.

What is claimed is:

1. An interposer, comprising:
an inner layer structure including at least one inner wiring layer;
a first outer layer structure disposed on a first surface of the inner layer structure, the first outer layer structure having rigidity higher than that of the inner layer structure; and
a second outer layer structure disposed on a second surface of the inner layer structure, the second outer layer structure having rigidity higher than that of the inner layer structure, wherein
the first outer layer structure covers at least the first surface of the inner layer structure,
the second outer layer structure covers at least the second surface of the inner layer structure,
the inner wiring layer includes wiring disposed on a surface of a first insulating resin layer, which is a photosensitive insulating resin, and a conductive member penetrating the first insulating resin layer and connected to the wiring,
the first outer layer structure includes a second insulating resin layer and a conductive member penetrating the second insulating resin layer,
the second outer layer structure includes a third insulating resin layer and a conductive member penetrating the third insulating resin layer,
the second insulating resin layer is a non-photosensitive resin containing a filler and no fiber substrate,
the third insulating resin layer is a non-photosensitive resin containing a filler and a fiber substrate, and
the first outer layer structure and/or the second outer layer structure includes a terminal connectable to a semiconductor device on a surface opposite to that connected to the inner layer structure, the terminal being capable of being subjected to electrical inspection.

2. The interposer of claim 1, wherein
in the wiring of the inner layer structure including at least one inner wiring layer, the wiring formed on an outermost layer on the second surface of the inner layer structure has a thickness of at least 1.5 times a thickness of the wiring formed inside the inner wiring layer.

3. The interposer of claim 1, wherein
a specimen of the interposer has a load/deflection ratio measured by the following measurement method of 0.125 N/mm or greater:
<measurement method>
a four-point bending test is performed on a horizontal surface of a specimen having dimensions of 80 mm length×15 mm width×h mm height (thickness of specimen) under conditions of a distance between supports L of 66 mm, an indenter radius r1 of 2 mm, and a distance between indenters of L′ of 22 mm at a test speed V calculated by the following formula:
$$\begin{matrix}[ Math . 1 ] & \\ V & ( 5 )\end{matrix}$$
$${ε}_{f}^{′} : strain rate [ 1 / min ]$$

4. The interposer of claim 1, wherein
the second and third insulating resin layers have physical properties of an elastic modulus of 5 GPa or greater and a CTE of 20 ppm or less,
the third insulating resin layer is formed of a prepreg,
the second insulating resin layer is formed of a built-up resin or a molding resin, and
a sum of thicknesses of the first outer layer structure and the second outer layer structure is greater than a thickness of the inner layer structure.

5. The interposer of claim 1, wherein
either the first outer layer structure or the second outer layer structure further covers a side surface of the inner layer structure.

6. The interposer of claim 1, further comprising
a built-in component embedded in the interposer, the built-in component being based on silicon, ceramic, glass or compound semiconductor, wherein
the first outer layer structure or the second outer layer structure includes a terminal electrically connected to the built-in component.

7. A semiconductor package in which a semiconductor device is mounted on the interposer of claim 1.

8. The semiconductor package of claim 7, wherein
a semiconductor device mounted on a connection terminal formed on a protruding electrode and a semiconductor device mounted on a connection terminal that does not form a protruding electrode are stacked and mounted.

9. The semiconductor package of claim 7, wherein
a plurality of the semiconductor packages are connected by the protruding electrode, and stacked.

10. A method of producing the interposer of claim 1, the method comprising:
a first step of forming a first outer layer structure on a support substrate;
a second step of forming an inner layer structure on an upper side of the first outer layer structure;
a third step of forming a second outer layer structure on an upper side of the inner layer structure;
a fourth step of releasing the first outer layer structure from the support substrate; and
a fifth step of forming a connection terminal on outermost layers of the first outer layer structure and second outer layer structure, wherein
the method further includes a step of mounting a built-in component.

11. A method of producing a semiconductor package, comprising the steps of:
a first inspection step of performing an electrical inspection of the interposer via a connection terminal;
a first determination step of determining whether the interposer is non-defective or defective based on a result of the first inspection step;
a preliminary connection step of mounting a semiconductor device on the interposer determined as “non-defective” in the first determination step;
a second inspection step of performing an electrical inspection of a semiconductor package preliminarily connected in the preliminary connection step;
a second determination step of determining whether the semiconductor package is non-defective or defective based on a result of the second inspection step;
a repair step of repairing and/or replacing the mounting of the semiconductor device determined as “defective” in the second determination step;
a third inspection step of performing an electrical inspection of the semiconductor package after the repair step;
a third determination step of determining whether the semiconductor package is non-defective or defective based on a result of the third inspection step; and
a fixing step of supplying an underfill into a gap between the semiconductor device and the interposer of the semiconductor package determined as “non-defective” in the third determination step.
